(19) United States
(12) Patent Application Publication
(10) Pub. No.: US 2025/0374500 A1
(43) Pub. Date: Dec. 4, 2025

(54) SEMICONDUCTOR DEVICE WITH THROUGH CONDUCTIVE FEATURE IN EDGE REGION

(71) Applicant: Taiwan Semiconductor Manufacturing Company, Ltd., Hsin-Chu (TW)

(72) Inventors: Jui-Lin Chen, Taipei City (TW); Lien-Jung Hung, Taipei (TW); Yung-Ting Chang, New Taipei City (TW); Yi-Feng Ting, Taipei City (TW)

(21) Appl. No.: 18/732,955

(22) Filed: Jun. 4, 2024

(51) Int. Cl. H10B 10/00; G11C 11/412; H01L 23/528

(52) U.S. Cl. CPC H10B 10/12; G11C 11/412; H01L 23/5286; H10B 10/18

(57) ABSTRACT

A semiconductor device includes a device layer, a frontside interconnect structure over the device layer and including a frontside power line, and a backside interconnect structure below the device layer and including a backside power line. The device layer includes a memory cell region including a plurality of memory cells, a logic region adjacent to a first edge of the memory cell region, and an edge region along a second edge of the memory cell region. The second edge is perpendicular to the first edge. The edge region includes a through conductive feature electrically connected to the frontside power line and the backside power line. The through conductive feature includes a backside via electrically connected to the backside power line, an epitaxial feature on the backside via, a source/drain contact on the epitaxial feature, and a top via on the source/drain contact and electrically connected to the frontside power line.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In deep sub-micron integrated circuit technology, static random-access memory (SRAM) device has become a popular storage unit of high-speed communication, image processing, and system-on-chip (SOC) products. The amount of embedded SRAM devices in microprocessors and SOCs increases to meet the performance requirement in new technology generations. As silicon technology continues to scale from one generation to the next, conventional SRAM devices and/or the fabrication thereof may encounter limitations. For example, aggressive scaling down of IC dimensions has resulted in densely spaced source/drain features and gate structures, and densely spaced source/drain contacts and gate vias formed thereover. In some SRAM devices, multilayer interconnect structure providing metal lines for interconnecting power lines and signal lines in and between memory cells of the SRAM devices are formed over source/drain contacts and gate vias of the transistors of the memory cells. With ever-decreasing device sizes and densely spaced transistors, some metal lines (e.g., metal lines for power routings) are formed to have reduced dimensions, which may lead to increased parasitic resistance, increased parasitic capacitance, high process risk, and/or poor connection, which may degrade the speed of the memory devices. All those issues present performance, yield, and cost challenges. Therefore, while existing SRAM devices may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a block diagram of a semiconductor device in accordance with some embodiments of the present disclosure.

FIG. 2 illustrates a circuit schematic for a static random-access memory (SRAM) cell, in accordance with some embodiments of the present disclosure.

FIG. 3A illustrates a perspective view of a multi-gate transistor, in accordance with some embodiments of the present disclosure.

FIG. 3B illustrates a cross-sectional view of various layers of the semiconductor device, in accordance with some embodiments of the present disclosure.

FIG. 4 illustrates an exemplary layout of the SRAM cell as in FIG. 2, in accordance with some embodiments of the present disclosure.

FIGS. 5, 6, and 7 illustrate an exemplary layout of a portion of the semiconductor device in an area A as in FIG. 1 in different levels, in accordance with some embodiments of the present disclosure.

FIG. 8 illustrates a diagrammatic cross-sectional view of the portion of the semiconductor device as in FIGS. 5, 6, and 7 along a B-B line, in accordance with some embodiments of the present disclosure.

FIGS. 9A and 9B illustrate cross-sectional diagrams of a portion of the semiconductor device as in FIGS. 1 and 5-7 along a C-C line and a D-D line in FIG. 1, respectively, in accordance with some embodiments of the present disclosure.

FIGS. 10, 12, 14, 15, 16, 17, 18, 19, 21, 22, 24, 25, and 26 illustrate layouts of a portion of alternative semiconductor devices in the area A as in FIG. 1, in accordance with some embodiments of the present disclosure.

FIG. 11 illustrates a diagrammatic cross-sectional view of the portion of the semiconductor device as in FIG. 10 along the B-B line, in accordance with some embodiments of the present disclosure.

FIG. 13 illustrates a diagrammatic cross-sectional view of the portion of the semiconductor device as in FIG. 12 along the B-B line, in accordance with some embodiments of the present disclosure.

FIG. 20A illustrates a diagrammatic cross-sectional view of the portion of the semiconductor device as in FIG. 19 along an E-E line, in accordance with some embodiments of the present disclosure.

FIG. 20B illustrates a cross-sectional diagram of a portion of the semiconductor device as in FIGS. 1 and 19 along the D-D line in FIG. 1, in accordance with some embodiments of the present disclosure.

FIGS. 23A and 23B illustrate diagrammatic cross-sectional views of the portion of the semiconductor device as in FIG. 22 along an E-E line and an F-F line, respectively, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

Static Random Access Memory (SRAM) is a semiconductor memory that retains data statically as long as it is powered. Unlike dynamic RAM (DRAM), SRAM is faster and more reliable, eliminating the need for constant refreshing. A memory device (e.g., an SRAM macro) includes memory cells in a memory cell region and logic cells in a logic cell region. The memory cells are also referred to as bit cells, and are configured to store memory bits. The memory cells may be arranged in rows and columns in forming an array. The logic cells may be standard cells (STD cells), such as inventor (INV), AND, OR, NAND, NOR, Flip-flip, SCAN and so on. The logic cell region is disposed adjacent to the memory cell region, and is configured to implement various logic functions. A memory device may include one or more edge regions adjacent to the memory cell region to isolate the memory cell region from environment or other parts of the memory device and to facilitate uniformity in fabrication.

Multilayer interconnect (MLI) structures provide metal tracks (metal lines) for interconnecting transistor gates and source/drain regions of memory cells, such as signal lines for routing bit line and word line signals to the cell components, as well as power rails (such as metal lines for power voltage and electrical ground) for providing power to the cell components. Contacts and respective contact vias electrically connect the cell components to the signal lines and the power rails. For example, some of the source/drain regions in an SRAM cell are coupled to a power voltage Vdd (also referred to as Vcc or a positive power supply voltage), and/or an electrical ground Vss through source/drain contacts, source/drain contact vias, and respective metal lines in the power rails. Source/drain region(s) may refer to a source or a drain, individually or collectively dependent upon the context. MLI structures also provides metal lines for interconnecting power lines and signal lines between the memory cells and logic cells.

With the increasing downscaling of memory devices, so do the power rails. As available layout area becomes limited and metal lines in the power rails are generally formed to have reduced dimensions. This inevitably leads to increased voltage drop across the power rails, as well as increased power consumption, which has become a key issue in further boosting performance of memory devices. Therefore, although existing approaches in semiconductor fabrication have been generally adequate for their intended purposes, they have not been entirely satisfactory in all respects in the context of memory devices.

The present disclosure is generally related to semiconductor devices, such as memory devices including a device layer. The device layer may include a memory cell region, a periphery region, memory edge regions, and power tap regions. The memory cells may include static random-access memory (SRAM) cells. The periphery region may be disposed adjacent to a first edge of the memory cell region and is configured to implement various logic functions. The memory edge regions may include dummy active regions and be disposed adjacent to a second edge and a third edge of the memory cell region perpendicular to the first edge. The memory device may further include frontside power lines and backside power lines disposed above and below the device layer, respectively. The present disclosure provides memory devices with various through conductive features disposed in the memory edge region(s) and electrically connected to the frontside power lines and/or the backside power lines, thereby reducing total resistance of power supply features (e.g., through conductive features, frontside power lines, backside power lines). Thus, voltage drop across the power supply features and power consumption may be reduced. By having the through conductive features, the memory devices disclosed herein may include an increased number of memory cells without impacting performance of the memory cells. In some embodiments, some regions (e.g., the power tap regions) of the memory device may be eliminated, which reduces the size of the memory device.

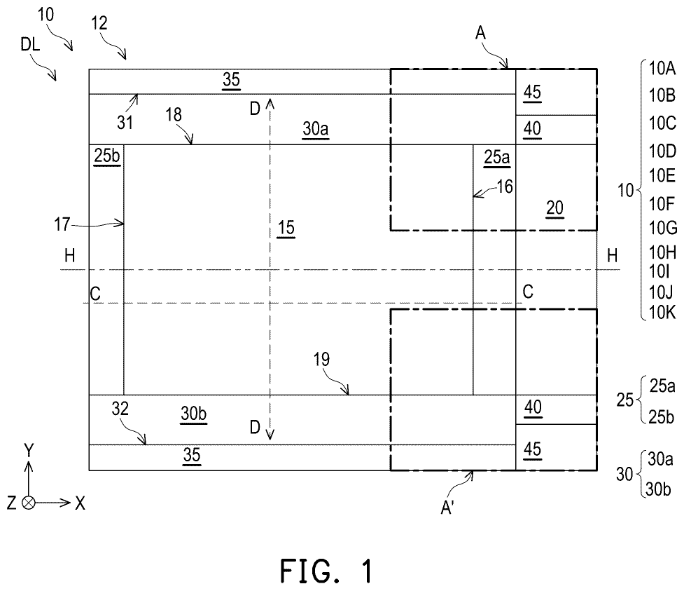

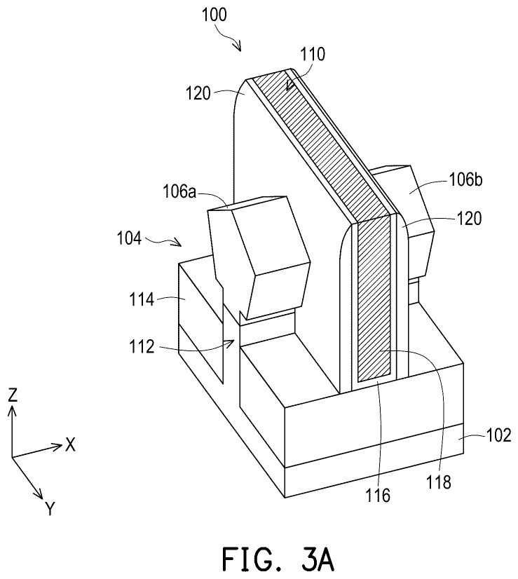

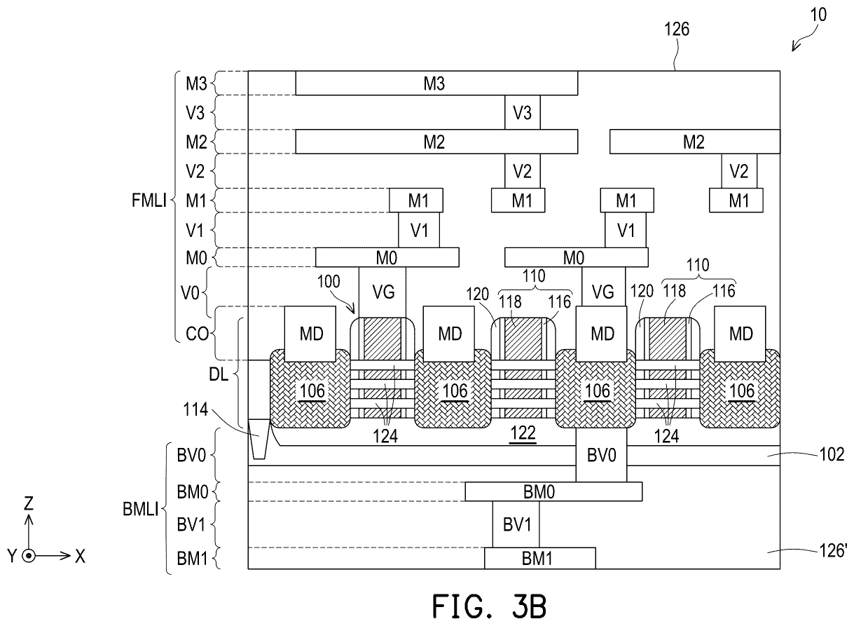

Reference now is made to FIG. 1. FIG. 1 is a simplified block diagram of a device layer (DL) of a memory device 10A. The memory device 10A may have various alternatives, such as memory devices 10B, 10C, 10D, 10E, 10F, 10G, 10H, 101, 10J, 10K, and 10L, which will be described below. For the purpose of simplicity, the various memory devices (e.g., the memory devices 10A, 10B, 10C, 10D, 10E, 10F, 10G, 10H, 101, 10J, 10K, and 10L) are labeled as memory device 10 in FIGS. 1 and 3. For clarity and simplicity, similar features in the memory devices 10A, 10B, 10C, 10D, 10E, 10F, 10G, 10H, 101, 10J, 10K, and 10L are identified by the same reference numerals, and similar aspects and benefits may not be repeated in the descriptions below. For avoidance of doubts, the X, Y and Z directions in the figures are perpendicular to one another and are used consistently throughout the present disclosure.

In some embodiments, the memory device 10A includes the device layer (DL), a frontside multilayer interconnect structure (FMLI) disposed over the DL, and a backside multilayer interconnect structure (BMLI) disposed below the DL. The DL may include a circuit macro (hereinafter, macro) 12. In some embodiments, the macro 12 is a static random-access memory (SRAM) macro, such as a single-port SRAM macro, a dual-port SRAM macro, or other types of SRAM macro. However, the present disclosure contemplates embodiments, where the macro 12 is another type of memory, such as a dynamic random-access memory (DRAM), a non-volatile random access memory (NVRAM), a flash memory, or other suitable memory. FIG. 1 has been simplified for the sake of clarity to better understand the inventive concepts of the present disclosure. Additional features can be added in the macro 12, and some of the features described below can be replaced, modified, or eliminated in other embodiments of the macro 12.

In some embodiments, the macro 12 includes a memory cell region 15 and a periphery region 20 adjacent to a first edge 16 of the memory cell region 15. The first edge 16 may be along the Y-direction. The memory cell region 15 includes memory cells (e.g., SRAM cells), which are also referred to as bit cells or functional memory cells, and are configured to store memory bits. The memory cell region 15 includes at least one memory cell. Generally, the memory cell region 15 may include many memory cells arranged in rows and columns of an array.

The periphery region 20 (also referred to as I/O periphery region 20) includes peripheral cells (also referred to as logic cells) configured to implement various logic functions. The logic functions of the logic cells include, for example, write and/or read decoding, word line selecting, bit line selecting, data driving and memory self-testing. The logic functions of the logic cells described above are given for the explanation purpose. Various logic functions of the logic cells are within the contemplated scope of the present disclosure. The periphery region 20 includes at least one logic cell. Generally, the periphery region 20 may include many logic cells to provide read operations and/or write operations to the memory cells in the memory cell region 15. The logic cells may be standard cells, such as inventor (INV), AND, OR, NAND, NOR, Flip-flip, SCAN and so on.

Transistors in the memory cell region 15 and the periphery region 20 may be implemented with various PFETs and NFETs such as planar transistors or non-planar transistors including various FinFET transistors, GAA transistors, or a combination thereof. GAA transistors refer to transistors having gate electrodes surrounding transistor channels, such as vertically-stacked gate-all-around horizontal nanowire or nanosheet MOSFET devices. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

In the depicted embodiment, the macro 12 includes power tap regions 25 (e.g., power tap region 25a and power tap region 25b, individually or collectively referred to as power tap region(s) 25 dependent upon the context) on the first edge 16 and a second edge 17 of the memory cell region 15, the first edge 16 and the second edge 17 being along the Y-direction. The power tap regions 25 may extend lengthwise along the Y-direction. The power tap regions 25a is between the memory cell region 15 and the periphery region 20 and serves as a transition from the memory cell region 15 to the periphery region 20. In some other embodiments, the macro 12 excludes the power tap region 25a and/or the power tap region 25b. In some embodiments, each of the power tap regions 25 includes an array of feedthrough vias (FTV, to be described below).

In some embodiments, the macro 12 includes memory edge regions 30 (e.g., memory edge region 30a and memory edge region 30b, individually or collectively referred to as memory edge region(s) 30 dependent upon the context) on a third edge 18 and a fourth edge 19 of the memory cell region 15. The third edge 18 and the fourth edge 19 are along the X-direction. The memory edge regions 30 may be adjacent to the power tap regions 25. The memory edge regions 30 may include dummy active regions and conductive features and are to be described below.

In some embodiments, the macro 12 includes memory filler regions 35 on edges 31 and 32 of the memory edge regions 30, and boundary regions 40 and standard cell fillers 45 in corners of the macro 12. The memory filler regions 35, boundary regions 40, and standard cell fillers 45 may each include dummy cells, dummy active regions, and/or well strap cells of various sizes. Dummy cells and/or dummy active regions may promote uniformity in fabrication and/or performance of the macro 12. Well strap cells may promote stability of potentials of N-wells and P-wells of the macro 12. Dummy cells are configured physically and/or structurally similar to an SRAM cell or a logic cell, but are non-functional (e.g., do not store data). Well strap cells generally refer to non-functional cells that are configured to electrically connect a voltage to an N-well, a P-well, or both. For example, an N-type well strap is configured to electrically couple an N-well that corresponds with at least one P-type transistor of an SRAM cell to a voltage source, and a P-type well strap is configured to electrically couple a P-well that corresponds with at least one N-type transistor of an SRAM cell to a voltage source.

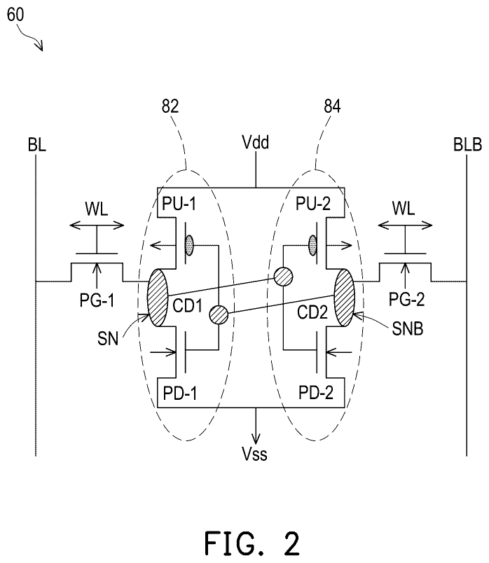

FIG. 2 is a circuit diagram of an exemplary SRAM cell 60, which can be implemented as a memory cell of a SRAM array, according to various aspects of the present disclosure. In some implementations, SRAM cell 60 is implemented in the memory cell region 15 of the macro 12 (FIG. 1). In the illustrated embodiment, the SRAM cell 60 is a single-port (SP) six-transistor (6T) SRAM cell. In various embodiments, the SRAM cell 60 may be other types of memory cells, such as dual-port memory cell or a memory cell having more than six transistors. FIG. 2 has been simplified for the sake of clarity to better understand the inventive concepts of the present disclosure. Additional features can be added in single-port SRAM cell 60, and some of the features described below can be replaced, modified, or eliminated in other embodiments of single-port SRAM cell 60.

The exemplary SRAM cell 60 includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 60, which includes a cross-coupled pair of inverters, an inverter 82 and an inverter 84. The inverter 82 includes the pull-up transistor PU-1 and the pull-down transistor PD-1, and the inverter 84 includes the pull-up transistor PU-2 and the pull-down transistor PD-2. In some implementations, the pull-up transistors PU-1, PU-2 are configured as P-type FinFET transistors or P-type GAA transistors, and the pull-down transistors PD-1, PD-2 are configured as N-type FinFET transistors or N-type GAA transistors.

A gate of the pull-up transistor PU-1 interposes a source (electrically coupled with a power supply voltage (Vdd)) and a first common drain (CD1), and a gate of pull-down transistor PD-1 interposes a source (electrically coupled with a power supply voltage (Vss), which may be an electric ground) and the first common drain. A gate of pull-up transistor PU-2 interposes a source (electrically coupled with the power supply voltage (Vdd)) and a second common drain (CD2), and a gate of pull-down transistor PD-2 interposes a source (electrically coupled with the power supply voltage (Vss)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

FIG. 3A illustrates a perspective view of a multi-gate transistor 100, which may serve as any transistor of the memory device 10, such as any of the transistors of the SRAM cell 60 (FIG. 2), including the pull-up transistor PU-1, the pull-up transistor PU-2, the pull-down transistor PD-1, the pull-down transistor PD-2, the pass-gate transistor PG-1, and the pass-gate transistor PG-2. In some embodiments, the multi-gate transistor 100 is a FinFET transistor that includes a channel region comprised of a fin-like structure. In some embodiments, the multi-gate transistor 100 is a GAA transistor that includes a channel region comprised of vertically-stacked horizontally-oriented nanostructures (e.g., nanowires or nanosheets).

In the illustrated embodiment, the multi-gate transistor 100 is formed on a substrate 102. The substrate 102 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 102 may be a single-layer material having a uniform composition. Alternatively, the substrate 102 may include multiple material layers having similar or different compositions suitable for IC device manufacturing. In one example, the substrate 102 may be a silicon-on-insulator (SOI) substrate having a semiconductor silicon layer formed on a silicon oxide layer. In another example, the substrate 102 may include a conductive layer, a semiconductor layer, a dielectric layer, other layers, or combinations thereof. Various doped regions, such as source/drain (S/D) regions, may be formed in or on the substrate 102. The doped regions may be doped with N-type dopants, such as phosphorus or arsenic, and/or P-type dopants, such as boron, depending on design requirements. The doped regions may be formed directly on the substrate 102, in a P-well structure, in an N-well structure, in a dual-well structure, or using a raised structure. Doped regions may be formed by implantation of dopant atoms, in-situ doped epitaxial growth, and/or other suitable techniques.

A three-dimensional active region 104 is formed on the substrate 102. An active region for a transistor refers to the area where a source region, a drain region, and a channel region under a gate structure of the transistor are formed.

Because the active regions are sometimes disposed in and defined by a silicon-oxide containing isolation feature (such as a shallow trench isolation, or STI), the active regions may be referred to as oxide-definition regions or “ODs”. The active region 104 includes a source region 106a, a drain region 106b, a channel region (under the gate structure 110) sandwiched by the source region 106a and the drain region 106b, and a fin base 112 on which the source region 106a, the drain region 106b, and the channel region are disposed on. The source region 106a and the drain region 106b are also individually or collectively referred to as the source/drain (S/D) region(s) 106. In some embodiments, the source/drain regions 106 are formed of epitaxially-grown features and are also referred to as source/drain features 106 or source/drain epitaxial features 106. The fin base 112 protrudes from the substrate 102. In a FinFET transistor, the channel region under the gate structure 110 may be a fin-like structure continuously extending upwardly from the fin base 112. In a GAA transistor, the channel region under the gate structure 110 may be vertically-stacked horizontally-oriented nanostructures suspended above the fin base 112. The suspended nanostructures connect the opposing source region 106a and drain region 106b.

An SRAM cell includes multiple active regions. In some embodiments, the formation of the active regions, such as the three-dimensional active regions 104 illustrated in FIG. 3A, includes patterning a top portion of the substrate in a patterning process. For example, the active regions 104 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the active region 104.

In some embodiments, an isolation structure 114 is deposited on sidewalls of the fin base 112. The isolation structure 114 may electrically isolate the active region 104 from other active regions. In some embodiments, the isolation structure 114 is shallow trench isolation (STI), field oxide (FOX), or another suitable electrically insulating features.

Still referring to FIG. 3A, in some embodiments, the gate structure 110 includes a gate dielectric 116 and a gate electrode 118 formed over the gate dielectric 116. In a FinFET transistor, the gate structure 110 is positioned over sidewalls and a top surface of a fin. In a GAA transistor, the gate structure 110 wraps around each of the channel layers (e.g., nanowire or nanosheet). Therefore, the gate structure 110 defines a portion of the active region 104 thereunder as a channel region. In some embodiments, the gate dielectric 116 is a high dielectric constant (high-k) dielectric material. A high-k dielectric material has a dielectric constant (k) higher than that of silicon dioxide. Examples of high-k dielectric materials include hafnium oxide, zirconium oxide, aluminum oxide, silicon oxynitride, hafnium dioxide-alumina alloy, hafnium silicon oxide, hafnium silicon oxynitride, hafnium tantalum oxide, hafnium titanium oxide, hafnium zirconium oxide, another suitable high-k material, or a combination thereof. In some embodiments, the gate electrode 118 is made of a conductive material, such as aluminum (Al), copper (Cu), tungsten (W), titanium (Ti), tantalum (Ta), or another applicable material.

In some embodiments, gate spacers 120 are deposited on sidewalls of the gate structure 110. In some embodiments, the gate spacers 120 are made of silicon nitride, silicon oxynitride, silicon carbide, another suitable material, or a combination thereof.

In some embodiments, portions of the active region 104 that are not covered by the gate structure 110 and the gate spacers 120 serve as the source/drain regions 106. In some embodiments, the source/drain regions 106 of P-type transistors, for example, the pull-up transistors PU-1, PU-2 are formed by implanting the portions of the active region 104 that are not covered by the gate structure 110 and the gate spacers 120 with a P-type impurity such as boron, indium, or the like. In some embodiments, the source/drain regions 106 of N-type transistors, for example, the pass-gate transistors PG-1, PG-2, the pull-down transistors PD-1, PD-2 are formed by implanting the portions of the active region 104 that are not covered by the gate structure 110 and the gate spacers 120 with an N-type impurity such as phosphorous, arsenic, antimony, or the like.

In some embodiments, the source/drain regions 106 are formed by etching portions of the active regions 104 that are not covered by the gate structure 110 and the gate spacers 120 to form recesses, and growing epitaxial features in the recesses. The epitaxial features may be formed of Si, Ge, SiP, SiC, SiPC, SiGe, SiAs, InAs, InGaAs, InSb, GaAs, GaSb, InAlP, InP, C, or a combination thereof. Accordingly, the source/drain regions 106 may be formed of silicon germanium (SiGe) in some exemplary embodiments, while the remaining active region 104 may be formed of silicon. In some embodiments, P-type impurities are in-situ doped in the source/drain regions 106 during the epitaxial growth of the source/drain regions 106 of P-type transistors, for example, the pull-up transistors PU-1, PU-2. In addition, N-type impurities are in-situ doped in the source/drain regions 106 during the epitaxial growth of the source/drain regions 106 of N-type transistors, for example, the pass-gate transistor PG-1, PG-2, the pull-down transistors PD-1, PD-2.

FIG. 3B is a fragmentary diagrammatic cross-sectional view of various layers (levels) that can be fabricated over and under a semiconductor substrate (or wafer) to form a portion of a memory device, such as the memory device 10 of FIG. 1, according to various aspects of the present disclosure. As represented in FIG. 3B, the various layers include the device layer (DL), the frontside multilayer interconnect structure (FMLI) disposed over the DL, and the backside multilayer interconnect structure (BMLI) disposed under the DL.

The DL includes devices (e.g., transistors, resistors, capacitors, and/or inductors) and/or device components (e.g., doped wells, gate structures, and/or source/drain features). In embodiments represented by FIG. 3, the DL includes the substrate 102, doped regions 122 (e.g., N-wells 122N and/or P-wells 122P) disposed in the substrate 102, the isolation structure 114, and transistors 100 as described above. In the depicted embodiment, transistors 100 include suspended channel layers (nanostructures) 124 and gate structures 110 disposed between source/drain features 106, where gate structures 110 wrap and/or surround suspended channel layers 124. Each gate structure 110 has a metal gate stack formed from a gate electrode 118 disposed over a gate dielectric layer 116. Gate spacers 120 are disposed along sidewalls of the metal gate stack.

The FMLI and the BMLI electrically couple various devices and/or components of the DL, such that the various devices and/or components can operate as specified by design requirements for the memory device. Each of the FMLI and the BMLI may include one or more interconnect layers. In the depicted embodiment, the FMLI includes a contact interconnect layer (CO level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the CO level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates FMLI having more or less interconnect layers and/or levels, for example, a total number of N interconnect layers (levels) of the FMLI with N as an integer ranging from 1 to 10. Each level of the FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the FMLI are collectively referred to as a dielectric structure 126. In some embodiments, conductive features at a same level of the FMLI, such as M0 level, are formed simultaneously. In some embodiments, conductive features at a same level of the FMLI have top surfaces that are substantially planar with one another and/or bottom surfaces that are substantially planar with one another.

In embodiments represented by FIG. 3B, the CO level includes source/drain contacts MD disposed in the dielectric structure 126. The source/drain contacts MD may be formed on and in direct contact with silicide layers disposed directly on the source/drain features 106. The V0 level includes gate vias VG disposed on the gate structures 110 and source/drain contact vias VD disposed on the source/drain contacts MD, where gate vias VG connect gate structures 110 to M0 metal lines, source/drain vias VD connect source/drain contacts MD to M0 metal lines. In some embodiments, the V0 level may also include butted contacts disposed in the dielectric structure 126. The V1 level includes V1 vias disposed in the dielectric structure 126, where V1 vias connect M0 metal lines to M1 metal lines. M1 level includes M1 metal lines disposed in the dielectric structure 126. V2 level includes V2 vias disposed in the dielectric structure 126, where V2 vias connect M1 metal lines to M2 metal lines. M2 level includes M2 metal lines disposed in the dielectric structure 126. V3 level includes V3 vias disposed in the dielectric structure 126, where V3 vias connect M2 metal lines to M3 metal lines.

In the depicted embodiment, the BMLI includes a backside via zero interconnect layer (BV0 level), a backside metal zero level (BM0 level), a backside via one interconnect layer (BV1 level) and a backside metal one interconnect layer (BM1 level). Each of the BV0 level, BM0 level, BV1 level, and BM1 level may be referred to as a metal level. Metal lines formed at the BM0 level may be referred to as BM0 metal lines. Similarly, via or metal lines formed at the BV0 level, BV1 level, and BM1 level may be referred to as BV0 vias, BV1 vias, and BM1 metal lines, respectively. The present disclosure contemplates BMLI having more or less interconnect layers and/or levels, for example, a total number of M interconnect layers (levels) of the BMLI with M as an integer ranging from 1 to 10. Each level of the BMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the BMLI are collectively referred to as a backside dielectric structure 126′. In some embodiments, conductive features at a same level of the BMLI, such as BM0 level, are formed simultaneously. In some embodiments, conductive features at a same level of the BMLI have top surfaces that are substantially planar with one another and/or bottom surfaces that are substantially planar with one another.

In embodiments represented by FIG. 3B, the BV0 level includes vias BV0 formed under the DL. For example, the vias BV0 may include one or more backside source/drain vias formed directly under the source/drain features 106 of the DL and coupled to those source/drain features 106 by way of a silicide layer. The vias BV0 may include one or more backside gate vias formed directly under and in direct contact with the gate structure(s) 110 of the DL. The BM0 level includes BM0 metal lines formed under the BV0 level. The backside gate vias (not depicted) connect gate structures 110 to BM0 metal lines, and the backside source/drain vias connect source/drain features to BM0 metal lines. The BV1 level includes BV1 vias disposed in the backside dielectric structure 126′, where BV1 vias connect BM0 metal lines to BM1 metal lines. The BM1 level includes BM1 metal lines formed under the BV1 level.

FIG. 3B has been simplified for the sake of clarity to better understand the inventive concepts of the present disclosure. Additional features can be added in the various layers of the memory, and some of the features described can be replaced, modified, or eliminated in other embodiments of the memory. FIG. 3B is merely an example and may not reflect an actual cross-sectional view of the memory device 10 that are described in further detail below.

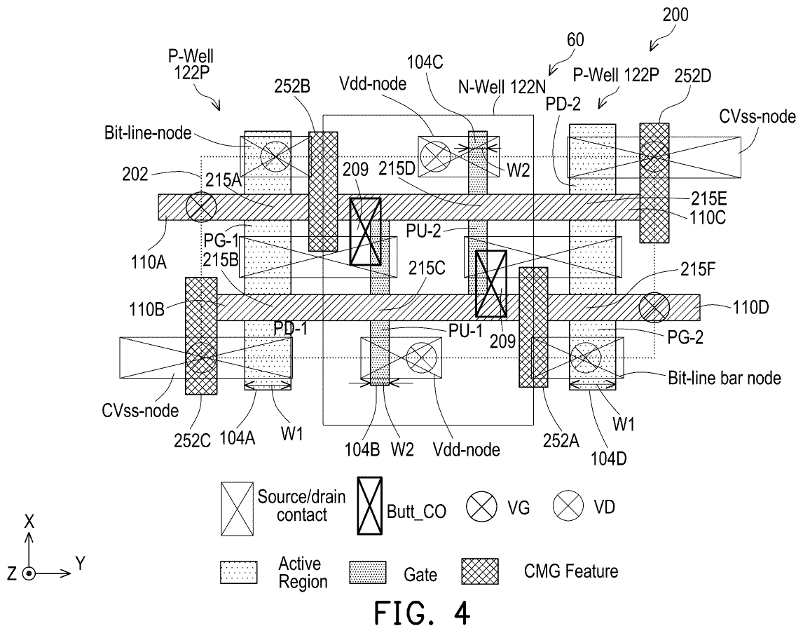

FIG. 4 illustrates an exemplary layout 200 of the SRAM cell 60 as in FIG. 2. A boundary of the SRAM cell 60 is illustrated in FIG. 4 using a rectangular box 202 with dotted lines. The rectangular box 202 is longer in the Y-direction than in the X-direction.

The SRAM cell 60 includes active regions 104 (such as active regions 104A, 104B, 104C, and 104D) that are oriented lengthwise along the X-direction, and gate structures 110 (such as gate structures 110A, 110B, 110C and 110D) that are oriented lengthwise along the Y-direction. The active regions 104B and 104C are disposed over an N-type well (or N-well) 122N. The active regions 104A and 104D are disposed over P-type wells (or P-wells) 122P that are on both sides of the N-well 122N along the Y-direction. The gate structures 110 engage the channel regions (e.g., 215A, 215B, . . . , 215F) of the respective active regions 104 to form transistors. In that regard, the gate structure 110A engages the channel region 215A of the active region 104A to form an N-type transistor as the pass-gate transistor PG-1; the gate structure 110B engages the channel region 215B of the active region 104A to form an N-type transistor as the pull-down transistor PD-1 and engages the channel region 215C of the active region 104B to form a P-type transistor as the pull-up transistor PU-1; the gate structure 110C engages the channel region 215E of the active region 104D to form an N-type transistor as the pull-down transistor PD-2 and engages the channel region 215D of the active region 104C to form a P-type transistor as the pull-up transistor PU-2; and the gate structure 110D engages the channel region 215F of the active region 104D to form an N-type transistor as the pass-gate transistor PG-2.

Different active regions in different transistors of the SRAM cell 60 may have same or different widths (e.g., dimensions measured in the Y-direction) in order to optimize device performance. In more detail, the active regions 104A and 104D may each have a first width W1 along the Y-direction, the active regions 104B and 104C may each have a second width W2 along the Y-direction. W2 may be equal to or smaller than W1. For example, a ratio of W1/W2 may range from about 1 to about 4. This may balance the speed among the N-type transistors and the P-type transistors to optimize SRAM performance.

Still referring to FIG. 4, the SRAM cell 60 further includes source/drain contacts disposed over the source/drain regions of the active regions 104 (the source/drain regions arc disposed on both sides of the respective channel region), a butted contact (Butt_CO) 209 disposed over and connecting the active region 104B and the gate structure 110C, another butted contact 209 disposed over and connecting the active region 104C and the gate structure 110B, source/drain contact vias (“VD”) disposed over and connecting to the source/drain contacts, and two gate vias (“VG”) disposed over and connecting to the gate structures 110A and 110D respectively. FIG. 4 further illustrates the circuit nodes Vss-node, Vdd-node, Bit-line-node, and Bit-line-bar-node (or BLB node), corresponding to the circuit nodes Vss, Vdd, BL, and BLB in FIG. 2. The bit-line-bar is also referred to as the complementary bit line or the inverse bit line. Also as illustrated in FIG. 4, in the layout 200, the source/drain contact vias VD and the gate vias VG may be positioned on the boundary of the SRAM cell 60 (e.g., positioned on the dotted lines of the rectangular box 202), as the source/drain contact vias VD and the gate vias VG may be shared by adjacent SRAM cells to electrically couple the respective same signal lines together.

Still referring to FIG. 4, the SRAM cell 60 further includes a plurality of gate-cut dielectric features extending lengthwise along the X-direction, including dielectric features 252A, 252B, 252C, 252D (collectively, dielectric features 252). In the illustrated embodiment, the dielectric feature 252A is disposed between the active regions 104C, 104D and abuts the gate structure 110B and the gate structure 110D. The dielectric feature 252A divides an otherwise continuous gate structure into two isolated segments corresponding to the gate structure 110B and the gate structure 110D. Similarly, the dielectric feature 252B is disposed between the active regions 104A, 104B and abuts the gate structure 110A and the gate structure 110C. The dielectric feature 252B divides an otherwise continuous gate structure into two isolated segments corresponding to the gate structure 110A and the gate structure 110C. The dielectric feature 252C is disposed between the active region 104A and the active region in an adjacent SRAM cell to the left of the SRAM cell 60 and separates the gate structure 110B from the gate structure in the adjacent SRAM cell. Similarly, the dielectric feature 252D is disposed between the active region 104D and the active region in an adjacent SRAM cell to the right of the SRAM cell 60 and separates the gate structure 110C from the gate structure in the adjacent SRAM cell. Each of the dielectric features 252 is formed by filling a corresponding cut-metal-gate (CMG) trench in the position of the dielectric features. The dielectric features 252 are also referred to as CMG features. In the illustrated embodiment, each of the dielectric features 252A, 252B is disposed above an interface between the N-well 122N and the respective P-well 122P, and the dielectric features 252C, 252D are disposed above the respective P-well 122P.

A CMG process refers to a fabrication process where after a metal gate (e.g., a high-k metal gate or HKMG) replaces a dummy gate structure (e.g., a polysilicon gate), the metal gate is cut (e.g., by an etching process) to separate the metal gate into two or more gate segments. Each gate segment functions as a metal gate for an individual transistor. An isolation material is subsequently filled into trenches between adjacent portions of the metal gate. These trenches are referred to as cut-metal-gate trenches, or CMG trenches, in the present disclosure. The dielectric material filling a CMG trench for isolation is referred to as a CMG feature. To ensure a metal gate would be completely cut, a CMG feature often further extends into adjacent areas, such as dielectric layers filling space between the metal gates. A CMG feature often have an elongated shape in a top view. For example, as shown in FIG. 4, each of the CMG features 252 has an elongated shape extending lengthwise in the X-direction.

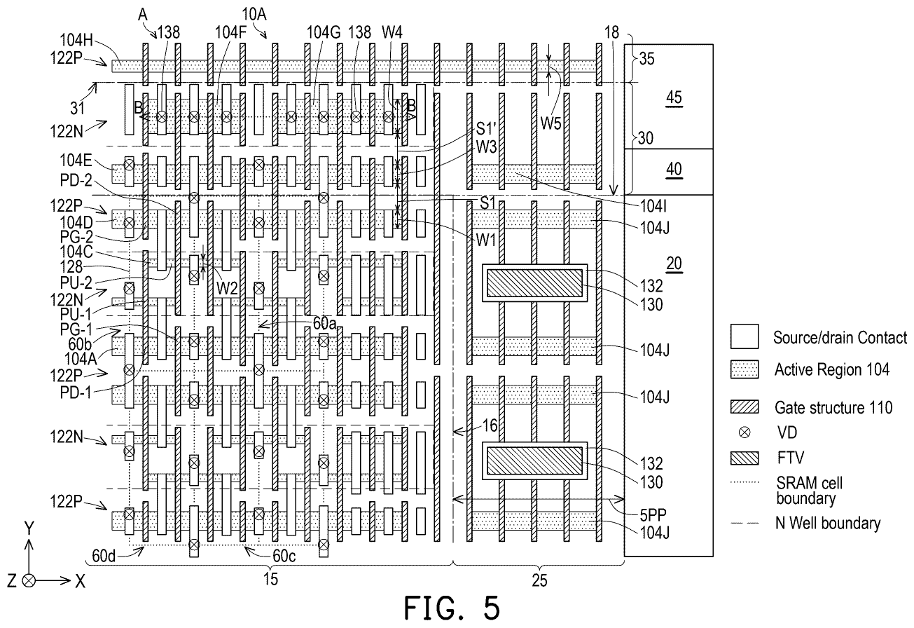

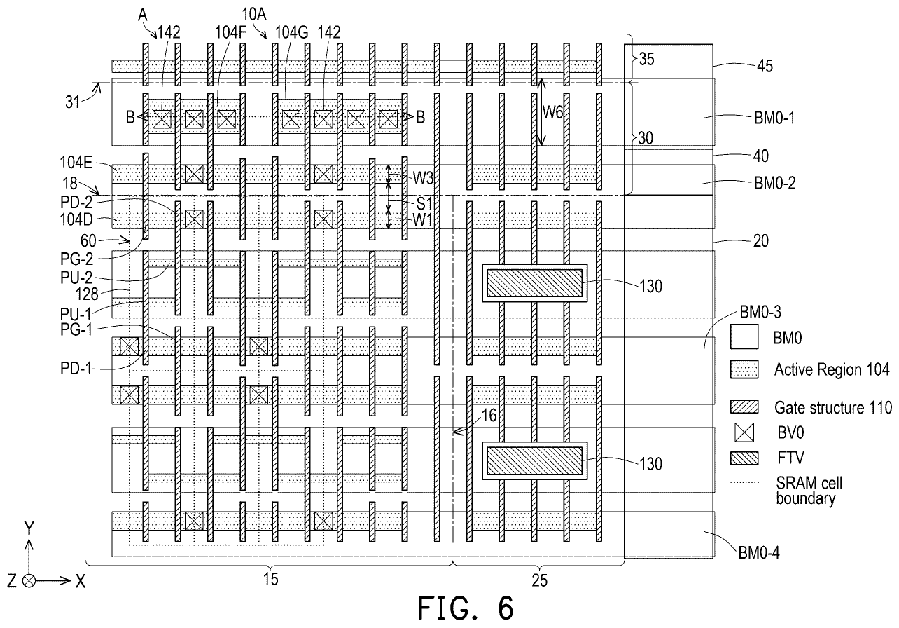

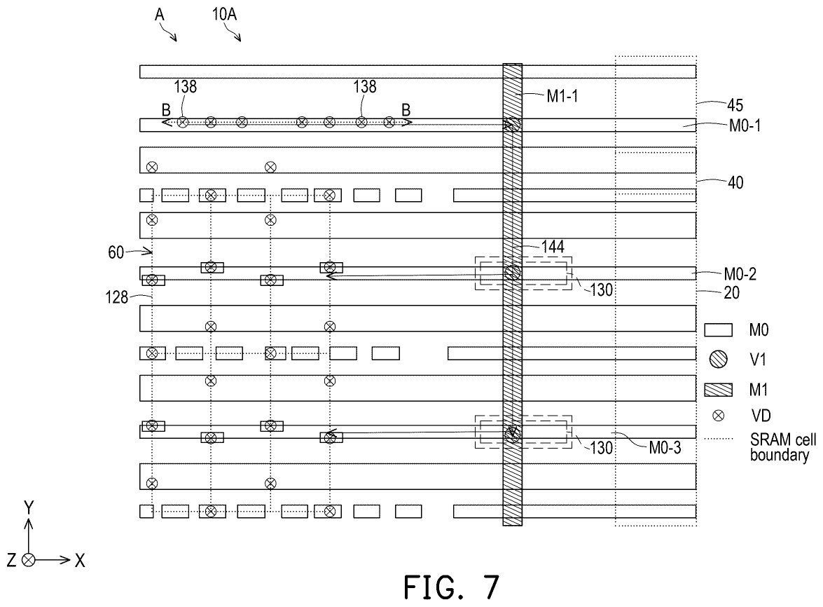

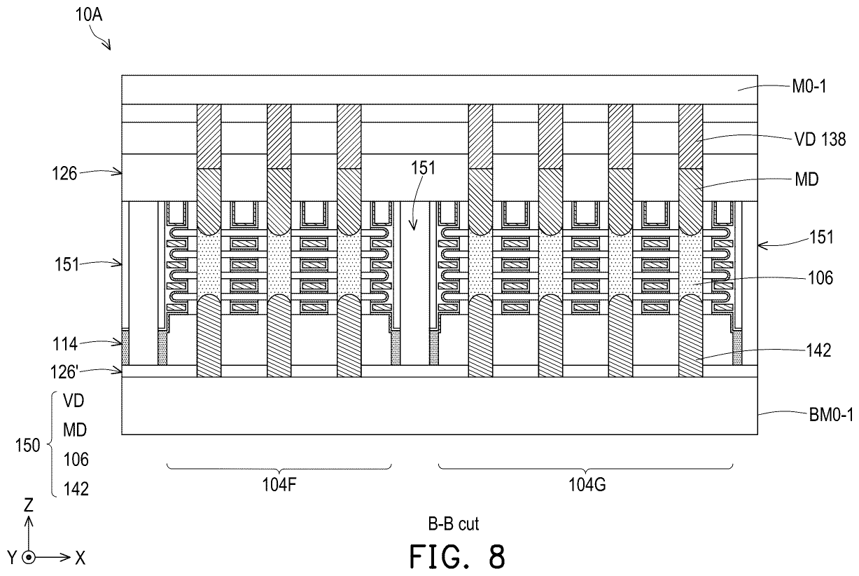

FIGS. 5-7 illustrate an exemplary layout of a portion of the memory device 10A in area A as in FIG. 1, in which FIG. 5 illustrates the DL level, CO level, and V0 level of the layout, FIG. 6 illustrates the DL level, BV0 level, and BM0 level of the layout, and FIG. 7 illustrates V0 level, M0 level, V1 level, and M1 level of the layout. FIG. 8 illustrates a cross-sectional view of the portion in area A of the memory device 10A along the B-B line as in FIGS. 5-7.

Referring to FIG. 6, for the purpose of simplicity, the layout inside the boundary regions 40, the standard cell fillers 45, and the periphery region 20 are not shown. Dashed lines 16, 18, and 31 illustrate the first edge 16 and the third edge 18 of the memory cell region 15, and the edge 31 of the memory edge region 30, respectively. As depicted, the memory device 10A includes N-wells 122N and P-wells 122P and a plurality of active regions 104 disposed over the N-wells 122N and the P-wells 122P. The active regions 104 disposed over the P-wells 122P may be N-type active regions (e.g., including source/drain features having N-type dopants). The active regions 104 disposed over the N-wells 122N may be P-type active regions (e.g., including source/drain features having P-type dopants). The active regions 104 are arranged along the Y-direction and extend lengthwise along the X-direction. As discussed above, in the memory cell region 15, the active regions 104 may have same or different widths along the Y-direction as described above. For example, in the memory cell region 15, the active regions 104 over the N-wells 122N each have the width W2, and the active regions 104 over the P-wells 122P each have the width W1. The gate structures 110 are disposed over the active regions 104 and extend lengthwise along the Y-direction. In the illustrated embodiment, the gate structures 110 are evenly distributed along the X-direction with a uniform distance between two adjacent gate structures 110. The uniform distance, which may be a minimum center-to-center distance between two adjacent gate structures 110 along the X-direction, is denoted as a gate pitch or a poly pitch (“PP”). The gate structures 110 intersect the active regions 104 in forming transistors, such as transistors 100 as described above. Transistors formed at the intersections of the active regions 104 and the gate structures 110 within the memory cell region 15 are devoted to form SRAM cells. Contacts, such as source/drain contacts MD, are disposed over and electrically connected to source/drain regions of the active regions 104. V0 vias (e.g., source/drain contact vias VD) may be disposed over the source/drain contacts MD. FIG. 5 has been simplified for the sake of clarity to better understand the inventive concepts of the present disclosure. For example, active regions 104, gate structures 110, source/drain contacts MD, and source/drain contact vias VD are shown, while some other features (e.g., gate vias VG, butted contacts, gate-cut dielectric features) are omitted in FIG. 5.

In the memory cell region 15, dotted lines 128 illustrate boundaries as rectangular boxes of SRAM cells. In the illustrated embodiment, the transistors in the memory cell region 15 form a plurality of SRAM cells 60 (e.g., SRAM cells 60a, 60b, 60c, 60d, collectively, SRAM cells 60) as described above. The SRAM cells 60 are arranged in the X-direction and the Y-direction, forming an array of SRAM cells. Each SRAM cell 60 in the array may use the layout 200 of the SRAM cell 60 as depicted in FIG. 4. In some embodiments, two adjacent SRAM cells 60 in the X-direction are line symmetric with respect to a common boundary therebetween, and two adjacent SRAM cells 60 in the Y-direction are line symmetric with respect to a common boundary therebetween. That is, the SRAM cell 60b is a duplicate cell for the SRAM cell 60a but flipped over the Y-axis; the SRAM cell 60c is a duplicate cell for the SRAM cell 60a but flipped over the X-axis; and the SRAM cell 60d is a duplicate cell for the SRAM cell 60b but flipped over the X-axis. The SRAM cells 60 may be repeated similarly in the array. Some active regions 104 extend through multiple SRAM cells in a row. For example, the active regions 104A and 104D extend through at least the SRAM cell 60b and the SRAM cell 60a.

In some embodiments, the memory edge region 30 includes a continuous active region 104E and discontinuous active regions (such as 104F, 104G, and 104I). In the depicted embodiment, the active regions 104E and 104I are over the P-well 122P and are N-type active regions, and the source/drain features 106 thereof are N-type source/drain features, while the active regions 104F and 104G are over the N-well 122N and are P-type active regions, and the source/drain features 106 thereof are P-type source/drain features. A width W3 of the active regions 104E and 104I along the Y-direction may be about the same as W1. In some embodiments, the active regions 104F and 104G each have a width W4 along the Y-direction. W4 may be equal to or wider than W1. In some embodiments, a ratio of W4 to W2 is in a range of about 3 to about 9. If W4 is too small, resistance of through conductive features formed through the active regions 104F and 104G may be too large, thus benefits of the disclosed structures may be too small. If W4 is too large, a distance S1′ between the active region 104G (or 104F) and the active region 104E may be too small, thus isolation between the active regions 104G/104F and 104E may be too small. The distance S1′ may be equal to or greater than a distance S1 between the active regions 104D and 104E. The memory edge region 30 may further include more discontinuous active regions aligned with and to the left of the active regions 104F and 104G along the X-direction and over the N-well 122N.

Referring to FIGS. 5 and 8, in some embodiments, the memory edge region 30 includes source/drain contacts MD disposed over the source/drain features 106 of the discontinuous active regions 104, such as the active regions 104F and 104G (for clarity and simplicity, also referred to as “MD over dummy OD”). The MD over dummy OD may each be disposed over only one source/drain feature 106. In the depicted embodiment, the MD over dummy OD are disposed over each of the source/drain features 106 of the active regions 104F and 104G. In some other embodiments, the MD over dummy OD are disposed over some of the source/drain features 106 of the active regions 104F and 104G. In other words, some of the source/drain features 106 of the active regions 104F and 104G do not have MD over dummy OD disposed thereover. In the depicted embodiment, the memory edge region 30 further includes source/drain contact vias VD (for clarity and simplicity, also referred to as VD 138) disposed over each of the MD over dummy OD.

In some embodiments, the memory filler region 35 includes an active region 104H disposed over one of the P-wells 122P. The active region 104H may have a width W5 along the Y-direction smaller than W1 and greater than W2.

In some embodiments, the power tap region 25 includes active regions 104J aligned with the active regions 104 over the P-wells 122P in the memory cell region 15 along the X-direction. The power tap region 25 further includes feed-through-vias (FTV) 130 between adjacent active regions 104J. The FTV 130 may be surrounded by a dielectric layer 132 from a top view. The dielectric layer 132 may isolate the FTV 130 from the surrounding gate structures 110. The dielectric layer 132 may include silicon oxide, a silicon oxide containing material, or a low-k dielectric layer such as TEOS oxide, undoped silicate glass (USG), doped silicon oxide such as BPSG, FSG, PSG, BSG, and/or other suitable dielectric material. In various examples, the dielectric layer 132 may be deposited by CVD, ALD, PVD, or combinations thereof. In embodiments, the FTV 130 are arranged along the Y-direction. The FTV 130 extend through the DL and may provide front-to-back electrical routes between the frontside multilayer interconnect structure FMLI and the backside multilayer interconnect structure BMLI and may each include one or more conductive features (e.g., a backside contact 134 and a frontside contact 136 disposed over the backside contact 134) connected together. The backside contact 134 may be in contact with a BM0 metal line and the frontside contact 136 may be in contact with an M0 metal line. The BM0 metal line and the M0 metal line may each be electrically connected to a power supply voltage (Vdd or Vss). In some embodiments, the backside contact 134 includes tungsten (W) and the frontside contact 136 includes aluminum (Al), copper (Cu), cobalt (Co), nickel (Ni), titanium (Ti), ruthenium (Ru), or tungsten (W). The one or more conductive features of the FTV 130 may be formed by performing a patterning and lithography process to form trenches through portions of the dielectric layer 132, then filling the trenches with metal features. In the depicted embodiment, the power tap region 25 has a span of five poly pitches between the first edge 16 of the memory cell region 15 and an opposing edge of the periphery region 20 along the X-direction.

Referring to FIGS. 6 and 8, the memory device 10A may further include backside vias BV0 disposed below the source/drain features 106 of the active regions 104F and 104G in the memory edge region 30 and some of the source/drain features 106 of the active regions 104 (e.g., 104D) in the memory cell region 15. The backside vias BV0 may electrically connect the corresponding source/drain features 106 and the BM0 metal lines (e.g., BM0-1, BM0-2, BM0-3, BM0-4) therebelow. For the purpose of clarity and simplicity, the backside vias BV0 disposed directly below the discontinuous active regions 104 in the memory edge region 30 (e.g., the active regions 104F and 104G) are also referred to as BV0 142. The BV0 142 may be disposed below each of the source/drain features 106 of the discontinuous active regions 104 in the memory edge region 30 and collectively form a discontinuous rail, which may be referred to as a BV0 rail. In the depicted embodiment, the metal line BM0-1 is a Vdd power line (e.g., a metal line electrically connected to Vdd potential, also referred to as a positive power supply line) and the metal lines BM0-2, BM0-3, and BM0-4 are Vss power lines (e.g., metal line electrically connected to Vss potential, also referred to as ground lines). Thus, the BV0 rail is electrically connected to a backside Vdd power line (e.g., the metal line BM0-1), and the backside vias BV0 other than the BV0 142 are electrically connected to backside Vss power lines. The FTV 130 may be electrically connected to the backside Vdd power lines (e.g., metal line BM0-1) or the backside Vss power lines (e.g., metal lines BM0-2, BM0-3, and BM0-4). The BM0 metal lines may have a width W6 along the Y direction. W6 may be greater than W4. In some embodiments, W6 is about a sum of the widths W1, W3, and the distance S1. The BM0 metal lines may extend from below the memory edge region 30 and the memory cell region 15 to below the standard cell fillers 45, the boundary region 40, and the periphery region 20.

Referring to FIGS. 7 and 8, the source/drain contact vias VD are connected to the M0 metal lines (e.g., metal lines M0-1, M0-2, M0-3) thereover. The M0 metal lines may extend from over the memory edge region 30 and the memory cell region 15 to over the standard cell fillers 45, the boundary region 40, and the periphery region 20. The M0 metal lines may be connected to a M1 metal line (e.g., metal line M1-1) by V1 via(s). For example, the metal lines M0-1, M0-2, and M0-3 are connected to the metal line M1-1 by V1 vias. In some embodiments, the metal lines M0-1, M0-2, and M0-3 are Vdd power lines. Thus, the source/drain features 106 of the active regions 104F and 104G in the memory edge region 30 are electrically connected to the Vdd power lines by the source/drain contacts MD (e.g., the MD over dummy OD) and source/drain contact vias VD (e.g., the VD 138). The arrows show an example electrical path 144 from the metal lines M0-1 to the other Vdd power lines M0-2 and M0-3. It is understood that the connections (e.g., the V1 vias and the metal line M1-1) between the metal lines M0-1, M0-2, and M0-3 are for illustration purpose only and should not be construed as limiting the scope of the present disclosure. The electrical path 144 may be formed by other connections. The FTV 130 may be electrically connected to the frontside Vdd power lines (e.g., metal lines M1-1, M0-1, M0-2, and M0-3) or frontside Vss power lines.

Referring to FIG. 8, in some embodiments, the memory device 10A includes through conductive features 150 in the memory edge region 30. Each of the through conductive features 150 may be formed through the discontinuous active regions (e.g., the active regions 104F and 104G) in the memory edge region 30 and may include a source/drain contact via VD, a source/drain contact MD, a source/drain feature 106, and a BV0 142. The memory edge region 30 may include a plurality of the through conductive features 150 arranged along the X-direction. The discontinuous active regions may be separated from each other by the isolation structures 114 and dielectric fin-cut features 151. The source/drain contact vias VD and the source/drain contacts MD may be surrounded by the dielectric structure 126, and the BV0 142 may be surrounded by the backside dielectric structure 126′.

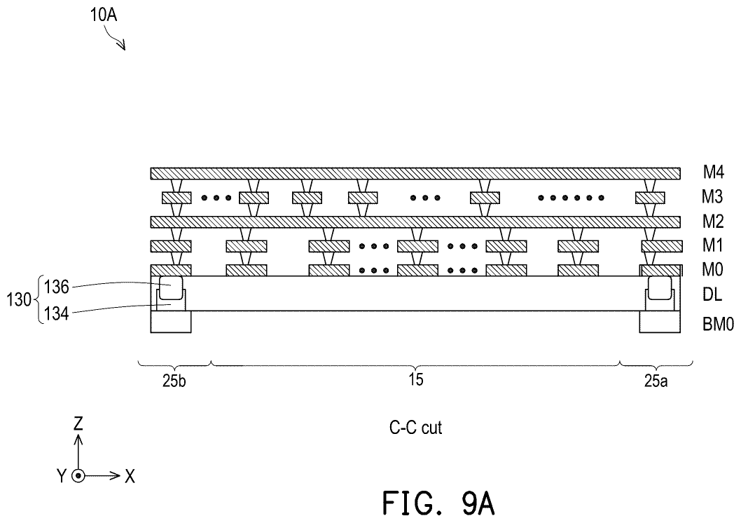

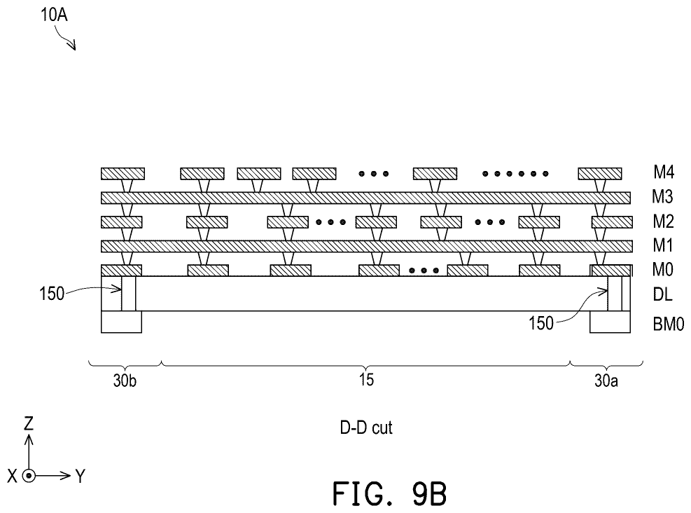

FIGS. 9A and 9B illustrate schematic side views of a portion of the memory device 10A along a C-C line and a D-D line as in FIG. 1, respectively. For the purpose of simplicity, structures in the device layer DL in the memory cell region 15 are not shown. The numbers of the metal lines and metal vias and connections among the metal lines and metal vias in FIGS. 9A and 9B are for illustration purpose only and should not be construed as limiting the scope of the present disclosure. The metal lines in FIG. 9A may include the same and/or different metal lines from the metal lines in FIG. 9B. Referring to FIG. 9A, the FTV 130 in the power tap regions 25a and 25b may be electrically connected to M0 metal lines, and then electrically connected to other metal lines in the FMLI. In embodiments, the FTV 130 are electrically connected to BM0 metal lines. The FTV 130 may be then electrically connected to other metal lines in the BMLI. The M0 metal lines and the BM0 metal lines may each include

Vdd and/or Vss power lines electrically connected to the FTV 130. Referring to FIG. 9B, the through conductive features 150 in the memory edge regions 30a and 30b may be electrically connected to the M0 metal lines, and then electrically connected to other metal lines in the FMLI. In embodiments, the through conductive features 150 are electrically connected to the BM0 metal lines. The through conductive features 150 may be then electrically connected to other metal lines in the BMLI. By having the through conductive features 150, additional conductive features (e.g., the through conductive features 150) are connected to the power lines in parallel, total resistance of power supply features (e.g., metal lines electrically connect to a voltage potential (such as Vdd or Vss) and the through conductive features 150) is reduced. Thus, voltage drop and/or power consumption on the power supply features during operation of the memory device 10A is reduced. The voltage drop may be reduced by greater than about 50 mV. By having the additional conductive features for power supply, the memory device 10A may include an increased number of memory cells without impacting performance of the memory cells.

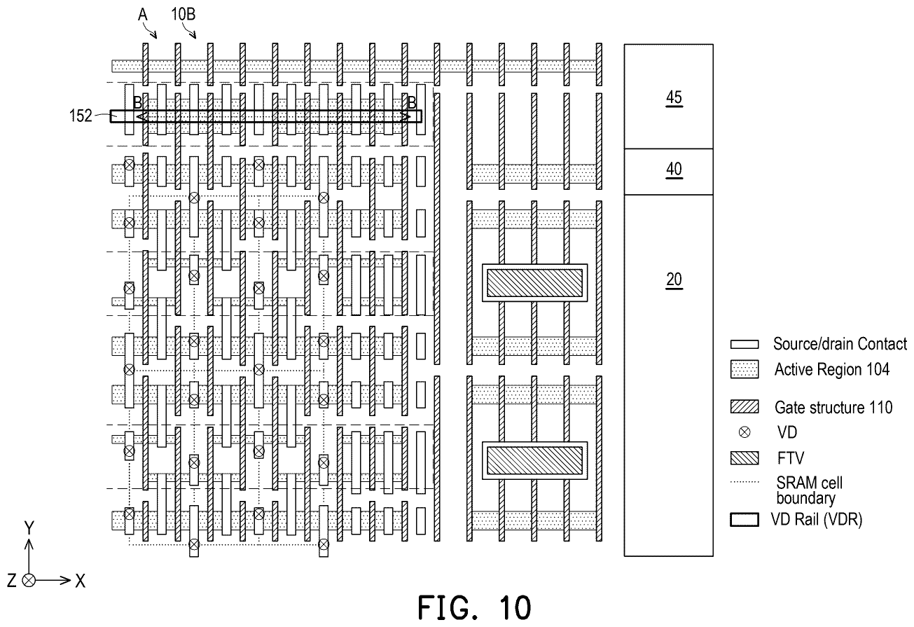

FIGS. 10 illustrates an exemplary layout of a portion of the alternative memory device 10B in area A as in FIG. 1 in DL level, CO level, and V0 level. Referring to FIG. 10, a difference from the memory device 10A as described for FIGS. 5-9B includes that, instead of the VD 138 disposed over the MD over dummy OD as in FIG. 5, the memory device 10B includes a source/drain contact via rail (VDR) 152 disposed over and connected to the MD over dummy OD. The VDR 152 may include similar materials as the VD 138, and may be formed using any suitable methods, such as performing a patterning and lithography process to form trenches through portions of the dielectric structure 126, then filling the trenches with metal features.

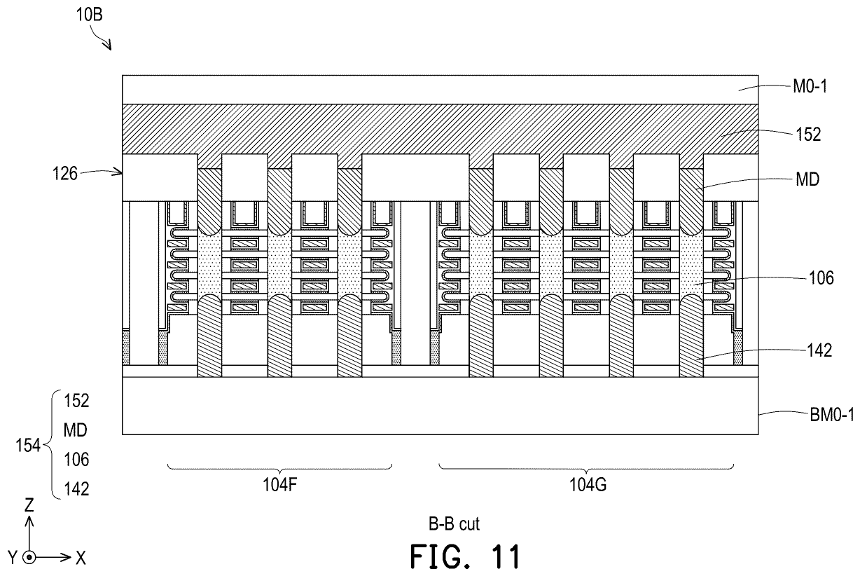

FIG. 11 illustrates a cross-sectional view of the portion of the memory device 10B as in FIG. 10 along B-B line. In such embodiments, the BV0 142, the source/drain features 106, the MD over dummy OD, and the VDR 152 collectively form a through conductive feature 154. The through conductive feature 154 electrically connects the metal line M0-1 and the metal line BM0-1. In embodiments, the through conductive feature 154 is further electrically connected to other frontside and/or backside metal lines. By having the VDR 152, the total resistance of power supply features may be further reduced from that in the memory device 10A.

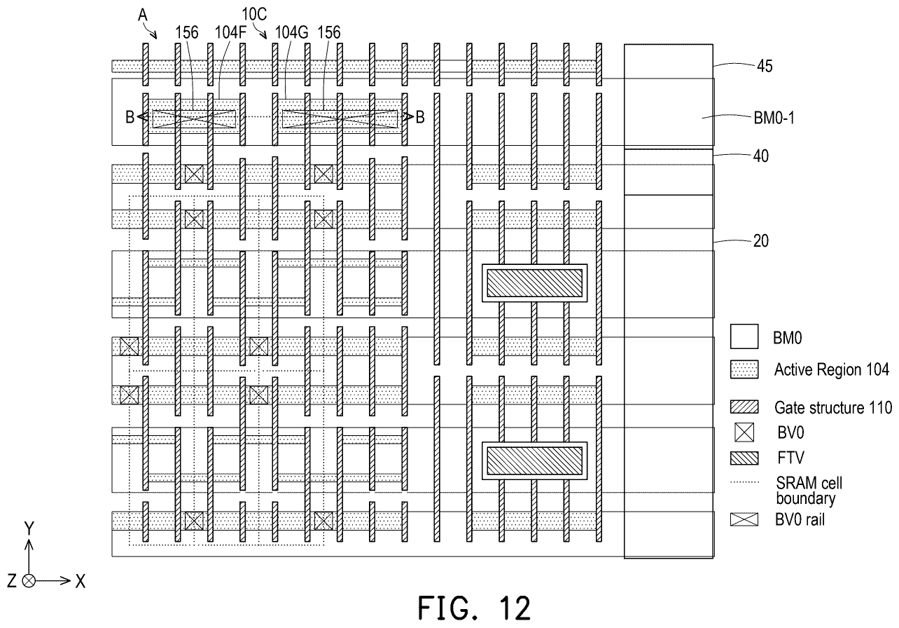

FIGS. 12 illustrates an exemplary layout of a portion of the alternative memory device 10C in area A as in FIG. 1 in DL level, BV0 level, and BM0 level. A difference from the memory device 10A as described for FIG. 5-9B includes that, instead of the BV0 142 as in FIG. 6, the memory device 10C includes a backside via bar 156 disposed below each of the discontinuous active regions (e.g., active regions 104F and 104G) and connected to the source/drain regions thereof. The backside via bar 156 may include similar materials as the BV0 vias (e.g., BV0 140) and may be formed using any suitable methods.

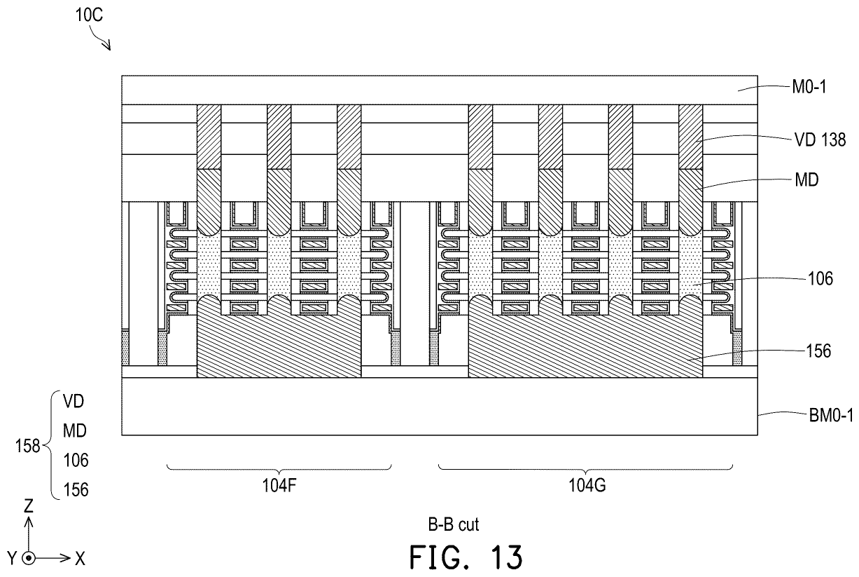

FIG. 13 illustrates a cross-sectional view of the portion of the memory device 10C as in FIG. 12 along B-B line. In such embodiments, the backside via bar 156, the source/drain features 106, the source/drain contacts MD, and the VD collectively form a through conductive feature 158. The through conductive feature 158 electrically connects the metal line M0-1 and the metal line BM0-1. In embodiments, the through conductive feature 158 is further electrically connected to other frontside and/or backside metal lines. By having the backside via bars 156, the total resistance of power supply features may be further reduced from that in the memory device 10A.

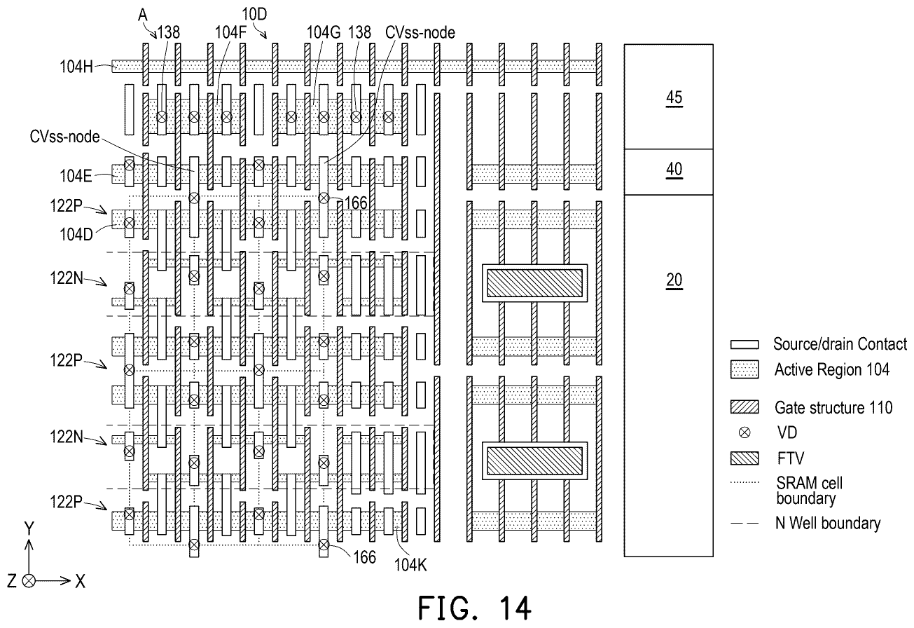

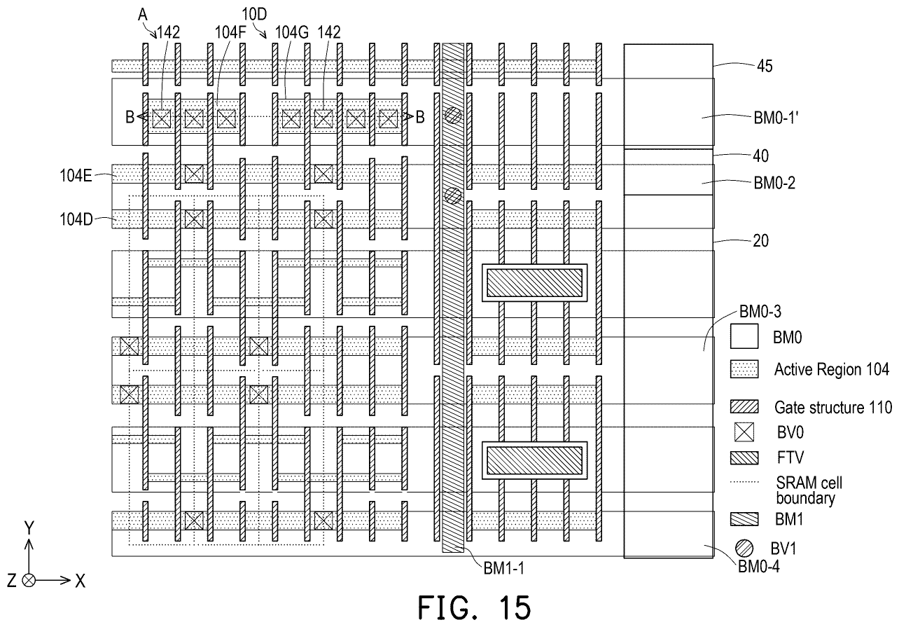

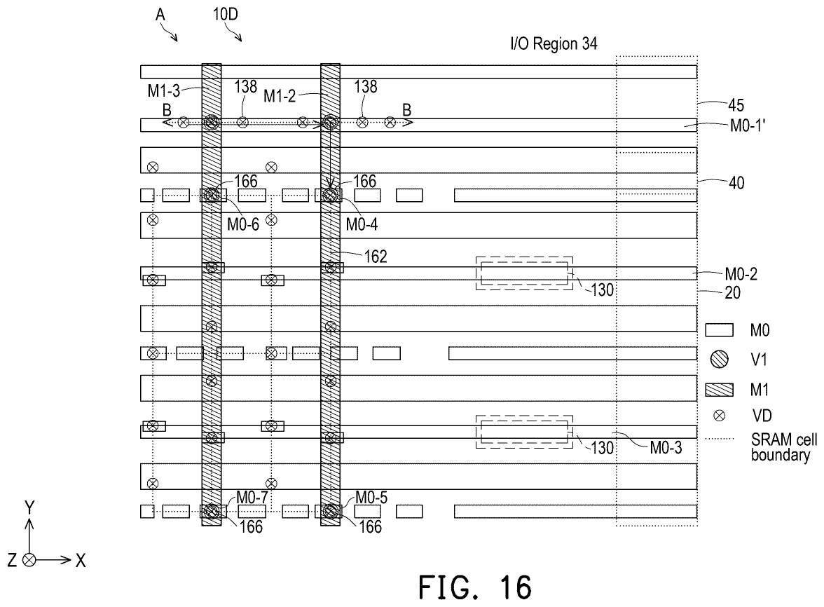

FIGS. 14-16 illustrate an exemplary layout of a portion of the alternative memory device 10D in area A as in FIG. 1, in which FIG. 14 illustrates the DL level, CO level, and V0 level of the layout, FIG. 15 illustrates the DL level, BV0 level, BM0 level, BV1 level, and BM1 level of the layout, and FIG. 16 illustrates V0 level, M0 level, V1 level, and M1 level of the layout.

Referring to FIG. 14, a difference of the memory device 10D from the memory device 10A as in FIG. 5 is that the active regions 104F, 104G, and 104H are over a same P-well 122P as the active regions 104E and 104D. Thus, the active regions 104F and 104G are N-type active regions and the source/drain features 106 thereof are N-type source/drain features. In some embodiments not depicted, the VD 138 may be replaced with a VD rail similar as the VD rail 152 in FIG. 10.

Referring to FIG. 15, a difference from the memory device 10A as in FIG. 6 is that the metal line BM0-1′ is a Vss power line. Thus, the metal lines BM0-1′ and BM0-2 may be both backside Vss power lines and may be electrically connected by a metal line BM1-1 by BV1 vias. The connection between the metal lines BM0-1′ and BM0-2, such as the metal line BM1 and the BV1 vias, are for illustration purpose only and their positions, dimensions, and numbers should not be construed as limiting the scope of the present disclosure. In some embodiments not depicted, the BV0 142 may be replaced with a backside via bars similar as the backside via bars 156 in FIG. 12. The FTV 130 may be electrically connected to backside Vdd power lines or the backside Vss power lines (e.g., the metal lines BM1-1, BM0-1′, BM0-2, BM0-3, and BM0-4).

Referring to FIG. 16, the VD 138 are electrically connected to the metal line M0-1′. A difference from the memory device 10A as in FIG. 7 is that the M0-1′ is a Vss power line. The metal line M0-1′ may be electrically connected to a metal line M1-2 by a V1 via. In some embodiments, the metal line M1-2 is a frontside Vss power line. In some embodiments, the metal line M1-2 is connected to metal lines M0-4 and M0-5 by V1 vias. The metal lines M0-4 and M0-5 may also be referred to as Vss landing pads. Similar to the through conductive features 150 in the memory device 10A, a through conductive feature of the memory device 10D in the memory edge region 30 includes the VD 138, the MD over dummy OD, the source/drain feature 106, and the BV0 142 from top to bottom. Thus, the through conductive feature of the memory device 10D is electrically connected to the frontside power line M0-1′ and the backside power line BM0-1′. The arrows 162 illustrate an example conductive path between the VD 138 and the source/drain contact vias VD (for clarity and simplicity, also referred to as VD 166) below the Vss pads (e.g., metal lines M0-4 and M0-5). In some embodiments, the metal line M0-1′ is also electrically connected to other Vss landing pads (e.g., metal lines M0-6 and M0-7) by other M1 metal line(s) (e.g., a metal line M1-3) and V1 vias. The metal lines M1-2 and M1-3 may be both Vss power lines. In some embodiments, the memory device 10D includes metal line(s) (e.g., M2 metal lines) higher than M1 level to electrically connect the metal line M1-2 and the other M1 metal line(s). The connection between the VD 138 and the VD 166, such as the metal lines M1-2, M1-3, and the V1 vias, are for illustration purpose only and their positions, dimensions, and numbers should not be construed as limiting the scope of the present disclosure. The FTV 130 may be electrically connected to the frontside Vdd power lines (e.g., metal lines M0-2, M0-3) or the frontside Vss power lines (e.g., metal lines M1-2, M1-3, M0-4, M0-5, M0-6, and M0-7).

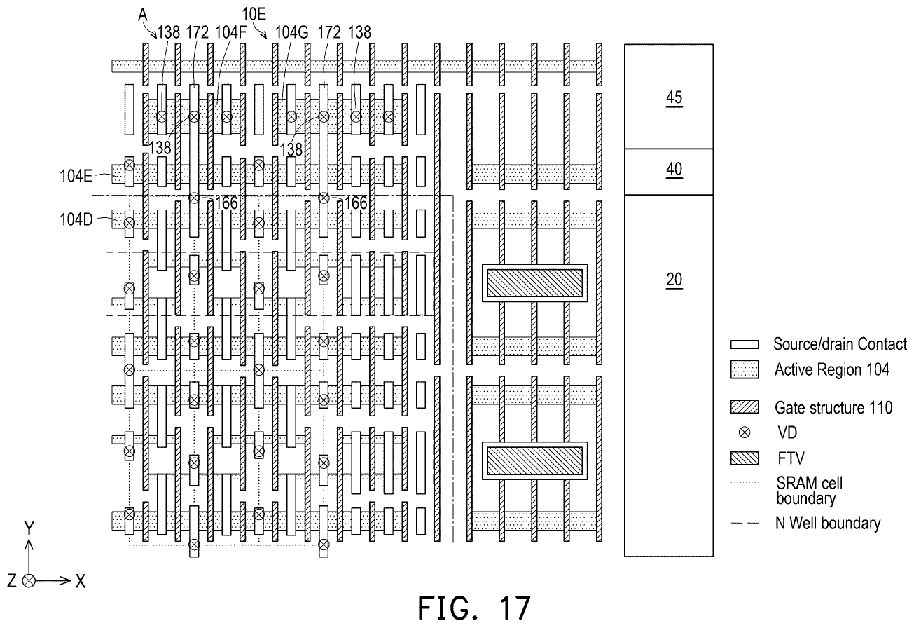

FIGS. 17 illustrates an exemplary layout of a portion of the alternative memory device 10E in area A as in FIG. 1 in DL level, CO level, and V0 level. A difference from the memory device 10D as described for FIGS. 14-16 includes that, instead of the source/drain contacts MD over the active regions 104D and 104E for circuit Vss-node (also referred to as “Vss-node MD”) and the MD over dummy OD aligned with the Vss-node MD, the memory device 10E includes extended source/drain contacts 172. The extended source/drain contacts 172 may extend continuously from the discontinuous active regions 104 (e.g., active regions 104F and 104G) to the active region 104D. In an example, the extended source/drain contact 172 extends continuously over the active regions 104D, 104E, and 104F and is electrically connected to the source/drain features 106 thereof. In another example, the extended source/drain contact 172 extends continuously over the active regions 104D, 104E, and 104G and is electrically connected to the source/drain features 106 thereof. The VD 138 and/or the VD 166 may be disposed over the extended source/drain contact 172. In some embodiments, the VD 138 are electrically connected to the metal lines M0-1′, and the VD 166 are electrically connected to the metal lines M0-4 and/or M0-6 as shown in FIG. 16. In such embodiments, the extended source/drain contacts 172 may reduce the total resistance of the Vss power supply features. In some other embodiments, the metal line M0-1′ and the connection between the M0-1′ and M0-4/M0-6 by the metal lines M1-2/M1-3 as shown in FIG. 16 may be eliminated. In other words, a through conductive feature of the memory device 10E may include the source/drain feature 106 of the discontinuous active regions (e.g., active regions 104F and 104G) and the BV0 142 from top to bottom, and may be connected to the Vss power line (e.g., the metal lines M0-4, M0-6, M1-2, and M1-3) by the extended source/drain contact 172.

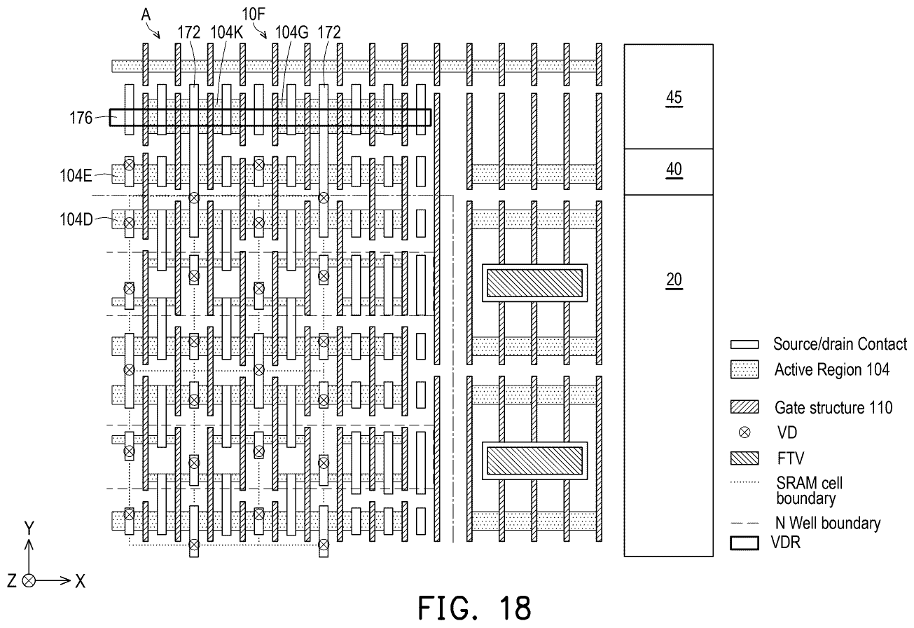

FIGS. 18 illustrates an exemplary layout of a portion of the alternative memory device 10F in area A as in FIG. 1 in DL level, CO level, and V0 level. Referring to FIG. 18, a difference from the memory device 10E as described for FIG. 17 includes that, instead of the VD 138, the memory device 10F includes a source/drain contact via rail (VDR) 176. The VDR 176 may be similar to the VDR 152 in FIG. 10. The VDR 176 may electrically connect the MD over dummy OD and the extended source/drain contacts 172 to the metal line M0-1′ as in FIG. 16.

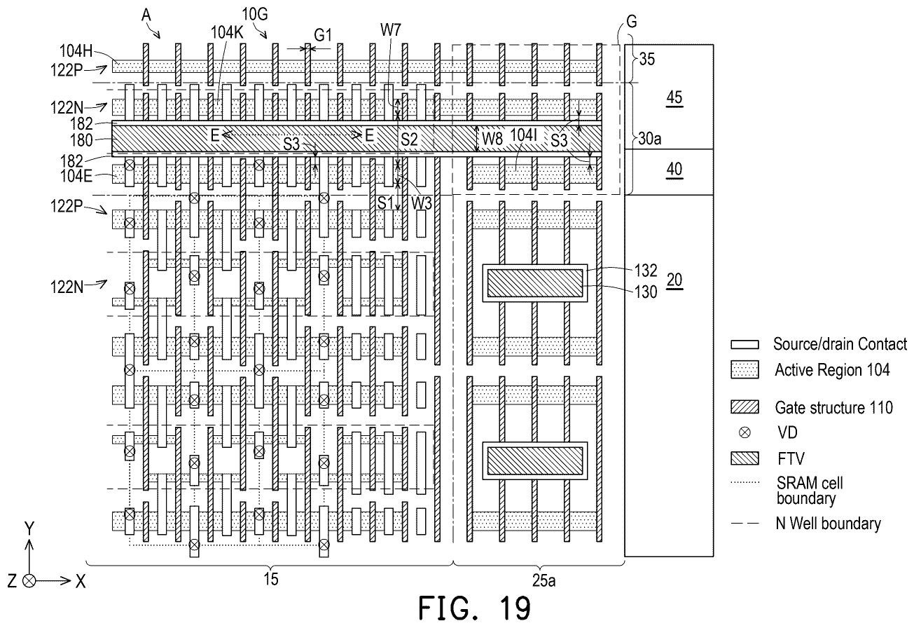

FIGS. 19 illustrates an exemplary layout of a portion of the alternative memory device 10G in area A as in FIG. 1 in DL level, CO level, and V0 level. Referring to FIG. 19, a difference from the memory device 10A as described for FIGS. 5-9B includes that, instead of the through conductive features 150, the memory device 10G includes a feed-through-via (FTV) rail 180 in the memory edge region 30. Another difference from the memory device 10A includes that, instead of discontinuous active regions 104F and 104G, the memory device 10G includes a continuous active region 104K in the memory edge region 30. In some embodiments, the FTV rail 180 is between the active regions 104K and 104E. The FTV rail 180 may also be disposed between the active regions 104K and 104I. In some other embodiments, the active region 104K is eliminated. The FTV rail 180 may extend lengthwise along the X-direction through the memory edge region 30 and extend vertically through the DL including the N-well 122N. Thus, the FTV rail 180 may be referred to as a through conductive feature 180. In some embodiments, the memory device 10G includes a dielectric layer 182 on sidewalls of the FTV rail 180. The dielectric layer 182 may isolate the FTV rail 180 from the adjacent conductive features, such as the gate structures 110, the source/drain features 106, and the source/drain contacts MD. The FTV rail 180 and the dielectric layer 182 may include similar materials as the FTV 130 and the dielectric layer 132, respectively. The FTV rail 180 and the dielectric layer 182 may be formed using any suitable method. In some embodiments, the method is similar to the method of forming the FTV 130 and the dielectric layer 132 as described above.

The active region 104K may have a width W7 along the Y-direction. W7 may be smaller than W4 as in FIG. 5. A distance S2 between the active regions 104K and 104E may be greater than the distance S1. In some embodiments, S2 is in a range of about 0.07 μm to about 0.15 μm. The dielectric layer 182 may be spaced apart from the active region 104E, 104I, or 104K by a distance S3. S3 may be in a range of about 0 μm to about 0.03 μm. The FTV rail 180 may have a width W8 in a range of about 0.02 μm to about 0.05 μm along the Y-direction. In some embodiments, a ratio of W8 to S2 is in a range of about 0.3 to about 1. In some embodiments, a ratio of W8 to W3 is in a range of about 1 to about 3. The gate structure 110 may have a width G1 along the X-direction. In some embodiments, a ratio of W8 to G1 is about 1 to about 6. If W8 is too small, resistance of the FTV rail 180 may be too large, thus benefits of the disclosed structures may be too small. If W8 is too large, it may unnecessarily increase the footprint of the memory device 10G and the costs associated therewith.

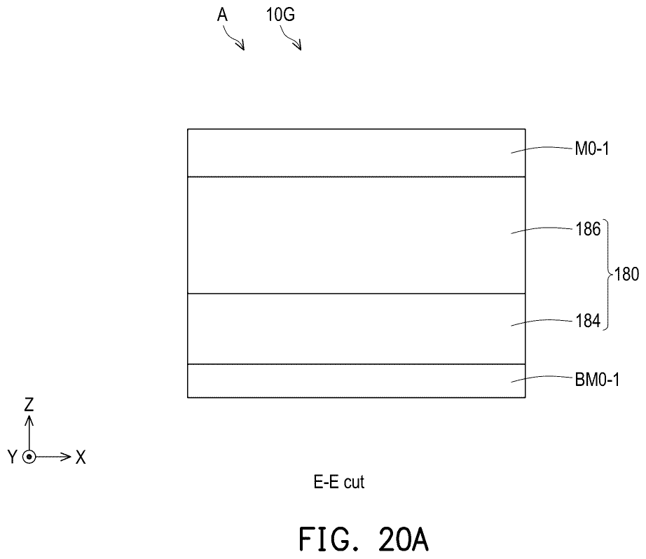

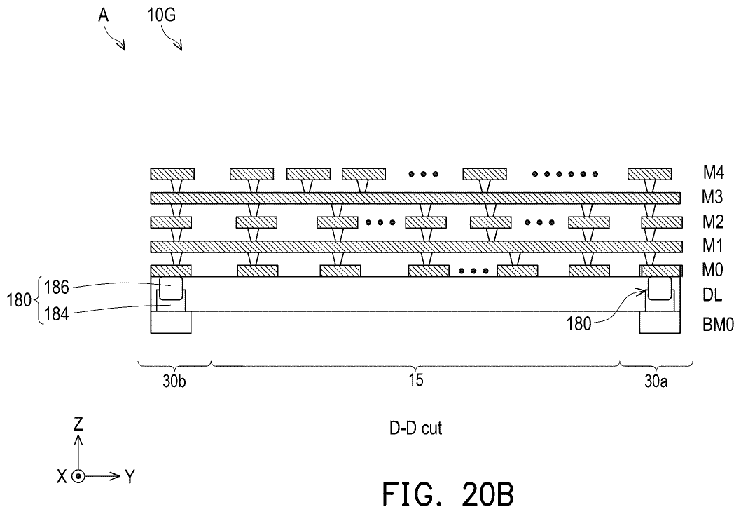

FIG. 20A illustrates a cross-sectional view of the portion of the memory device 10G as in FIG. 19 along an E-E line. The FTV rail 180 may include one or more conductive features (e.g., conductive rails 184 and 186) connected together. The metal line M0-1 as in FIG. 7 is disposed above and connected to the conductive rail 186. The metal line BM0-1 as in FIG. 6 is disposed below and connected to the conductive rail 184.

FIG. 20B illustrates a schematic side view of a portion of the memory device 10G along the D-D line as in FIG. 1. For the purpose of simplicity, structures in the device layer DL in the memory cell region 15 are not shown. The numbers of the metal lines and metal vias and connections between the metal lines and metal vias in FIG. 20B are for illustration purpose only and should not be construed as limiting the scope of the present disclosure. A difference from the memory device 10A as in FIG. 9B is that, instead of the through conductive features 150, the memory device 10G includes the FTV rails 180 connecting the M0 and BM0 metal lines. The FTV rails 180 may then be electrically connected to other metal lines in the FMLI and other metal lines in the BMLI. By replacing the through conductive features 150 with the FTV rail 180, the total resistance of the power supply features (e.g., metal lines electrically connect to a voltage potential (such as Vdd or Vss) and the FTV rail 180) is further reduced compared to the memory device 10A. Thus, voltage drop and/or power consumption on the power supply features during operation of the memory device 10G may be further reduced. The voltage drop may be reduced by greater than about 150 mV.

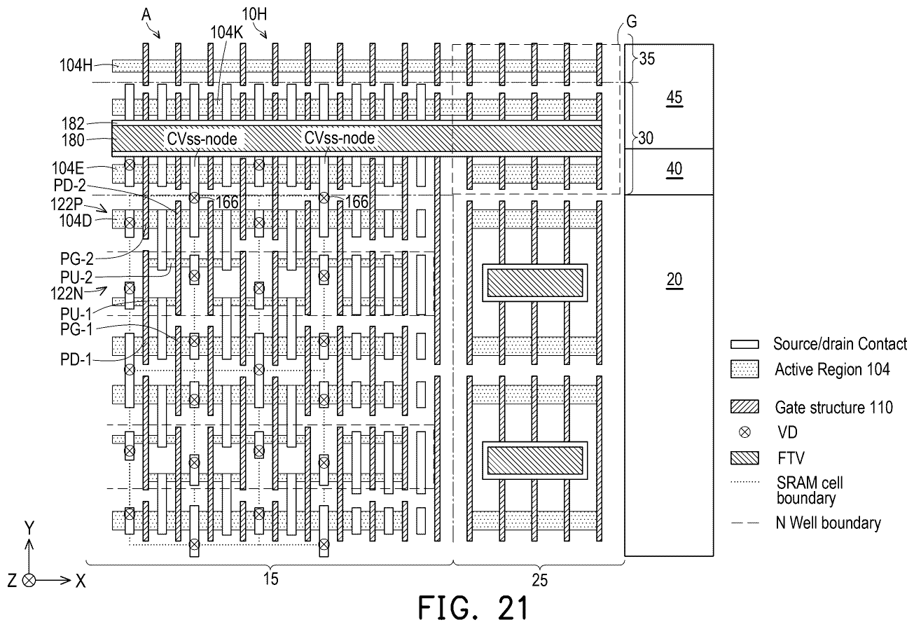

FIGS. 21 illustrates an exemplary layout of a portion of the alternative memory device 10H in area A as in FIG. 1 in DL level, CO level, and V0 level. Referring to FIG. 21, differences from the memory device 10D as described for FIGS. 14-16 include that, instead of the through conductive features, the memory device 10H includes an FTV rail 180 in the memory edge region 30, and instead of the discontinuous active regions 104F and 104G, the memory device 10G includes a continuous active region 104K in the memory edge region 30. The active regions 104D, 104E, 104K, and 104H of the memory device 10H are over the same P-well 122P. The FTV rail 180 may extend lengthwise along the X-direction through the memory edge region 30 and extend vertically through the DL including the same P-well 122P. Similar as the through conductive features of the memory device 10D, the FTV rail 180 may be disposed below and electrically connected to the metal line M0-1′ as in FIG. 16, and may be disposed above and electrically connected to the metal line BM0-1′ as in FIG. 15. The FTV rail 180, the dielectric layer 182, and the continuous active region 104K, their relative positions and dimensions, etc. are similar as descried above for the memory device 10G.

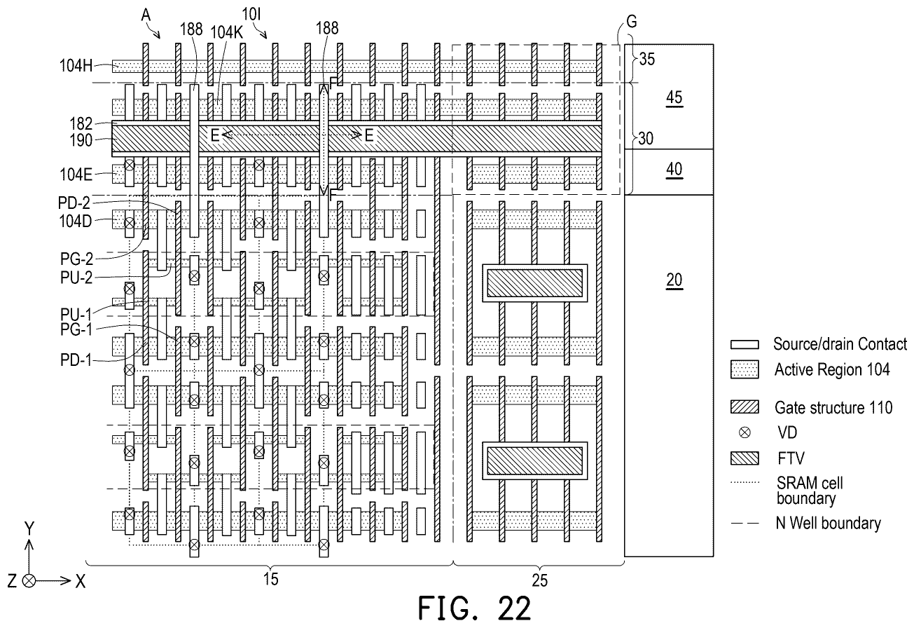

FIGS. 22 illustrates an exemplary layout of a portion of the alternative memory device 101 in area A as in FIG. 1 in DL level, CO level, and V0 level. Referring to FIG. 22, differences from the memory device 10H as described for FIG. 21 include that, instead of the

Vss-node MD, the VD 166, and the source/drain contacts MD aligned to the Vss-node MD and over the active region 104K, the memory device 101 includes extended source/drain contacts 188 disposed over electrically connected to the FTV rail 190 and the source/drain features 106 of the active regions 104D, 104E, and 104K. In some other embodiments, the active region 104K is eliminated and the extended source/drain contacts 188 do not extend to be over the active region 104K. In some embodiments, the extended source/drain contacts 188 are electrically connected to the metal lines M0-1′, M0-4, and/or M0-6 as in FIG. 16, which are frontside Vss power lines. Thus, the extended source/drain contacts 188 are Vss contacts. In such embodiments, the extended source/drain contacts 188 may reduce the total resistance of the Vss power supply features. In some other embodiments, the metal line M0-1′ and the connection between the M0-1′ and M0-4/M0-6 by the metal lines M1-2/M1-3 as in FIG. 16 may be eliminated.

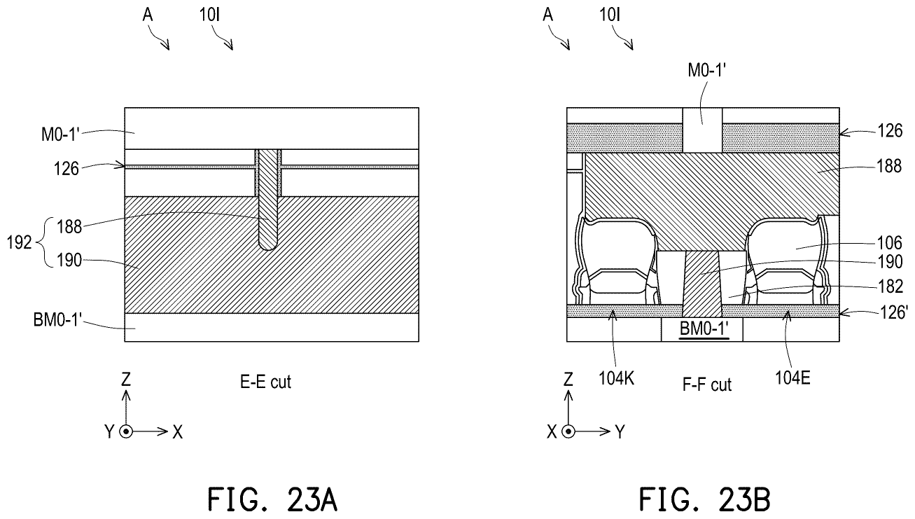

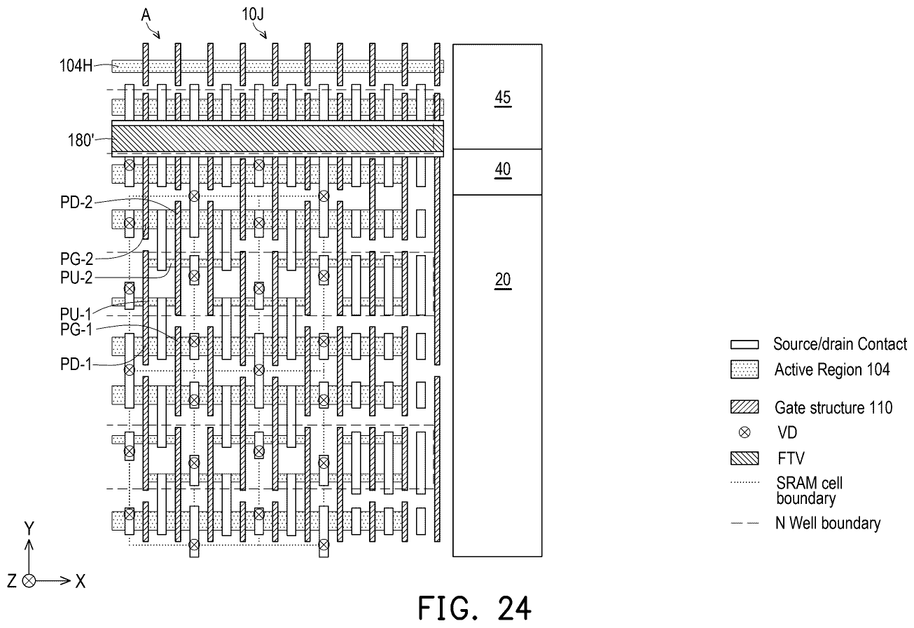

FIGS. 23A and 23B illustrate cross-sectional views of the portion of the memory device 101 as in FIG. 22 along an E-E line and an F-F line, respectively. In the depicted embodiment, the FTV rail 190 is disposed below and connected to the extended source/drain contact 188. The FTV rail 190 and the extended source/drain contact 188 collectively form a through conductive feature 192, which is electrically connected to the metal lines M0-1′ and BM0-1′. Differences from the FTV rail 180 in FIG. 21 include that, the FTV rail 190 has a height along the Z-direction smaller than a height of the FTV rail 180 along the Z-direction, and that the FTV rail 190 does not directly contact the metal line M0-1′. The FTV rail 190 may be spaced apart from the metal line M0-1′ by the dielectric structure 126 and the extended source/drain contact 188 as depicted. The FTV rail 190 may be disposed above and directly contact the metal line BM0-1′.

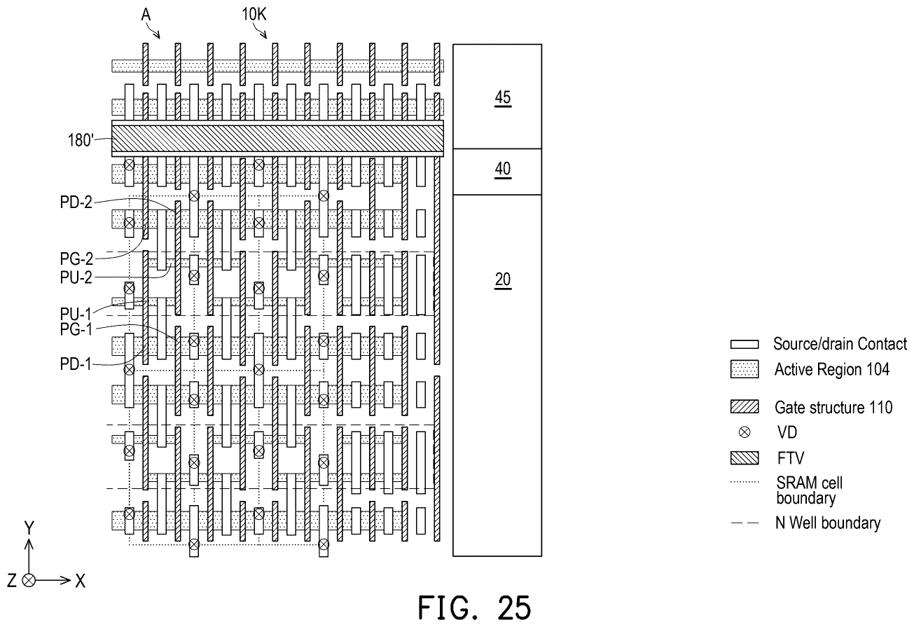

FIGS. 24 illustrates an exemplary layout of a portion of the alternative memory device 10J in area A as in FIG. 1 in DL level, CO level, and V0 level. Referring to FIG. 24, a difference from the memory device 10G as described for FIGS. 19 and 20A-20B includes that, the power tap region 25a and an aligned portion (e.g., in an area G) of the memory edge region 30 and the memory filler region 35 are eliminated, thus five poly pitches (PP) is reduced from the total width of the macro 12. The area G is illustrated by the dashed rectangle and is aligned with the power tap region 25a along the Y direction. Similarly, the power tap region 25b and a corresponding aligned portion of the memory edge region 30 and the memory filler region 35 may also be eliminated, thus five PP is reduced from the total width of the macro 12. Thus, the footprint area of the macro 12 of the memory device 10J may be reduced from that of the memory device 10G by about 2% to about 30%. In such embodiments, power supply to the memory cells of the memory cell region 15 may be provided by the FTV rail 180′, which extends through the memory edge region 30 and is similar but shorter than the FTV rail 180 along the X-direction. By having the FTV rail 180′ and eliminating the power tap regions 25 and the aligned portion(s), total resistance of power supply features (e.g., metal lines electrically connect to a voltage potential (such as Vdd or Vss) and the FTV rail 180′) may be reduced. Thus, voltage drop and/or power consumption on the power supply features during operation of the memory device 10J may be reduced. The voltage drop may be reduced by greater than about 80 mV.

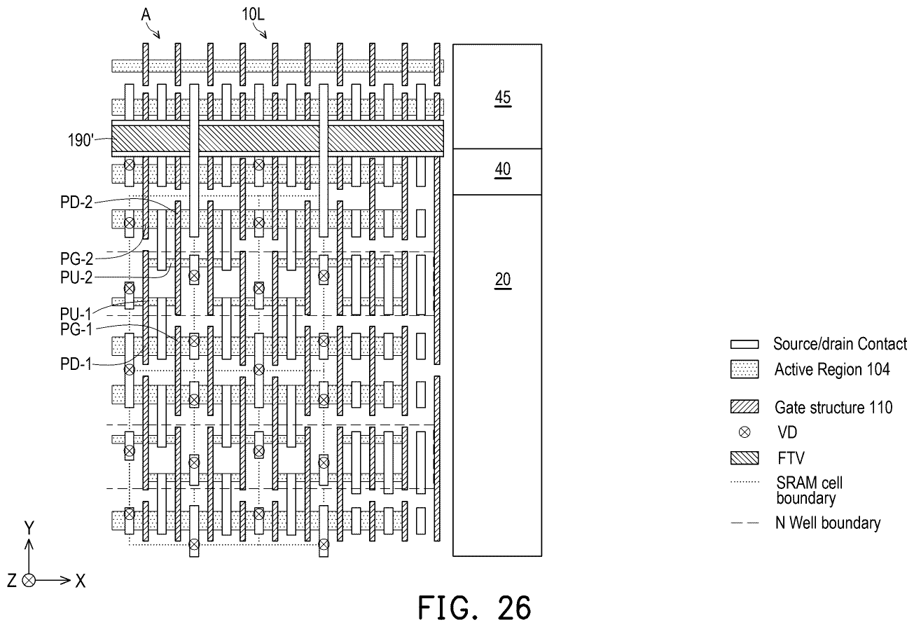

FIGS. 25 illustrates an exemplary layout of a portion of the alternative memory device 10K in area A as in FIG. 1 in DL level, CO level, and V0 level. Referring to FIG. 25, a difference from the memory device 10H as described for FIG. 21 includes that, the power tap region 25a and an aligned portion (e.g., in an area G) of the memory edge region 30 and the memory filler region 35 are eliminated, thus five poly pitches (PP) is reduced from the total width of the macro 12. The area G is illustrated by the dashed rectangle and is aligned with the power tap region 25a along the Y direction. Similarly, the power tap region 25b and a corresponding aligned portion of the memory edge region 30 and the memory filler region 35 may also be eliminated, thus five poly pitches (PP) is reduced from the total width of the macro 12. Thus, the footprint area of the macro 12 of the memory device 10K is reduced from that of the memory device 10H by about 2% to about 30%. In such embodiments, power supply to the memory cells of the memory cell region 15 may be provided by the FTV rail 180′, which extends through the memory edge region 30 and is similar but shorter than the FTV rail 180 along the X-direction. Similar as described above for FIG. 24, the voltage drop may be reduced by greater than about 80 mV.

FIGS. 26 illustrates an exemplary layout of a portion of the alternative memory device 10L in area A as in FIG. 1 in DL level, CO level, and V0 level. Referring to FIG. 26, a difference from the memory device 101 as described for FIGS. 22-23B includes that, the power tap region 25a and an aligned portion (e.g., in an area G) of the memory edge region 30 and the memory filler region 35 are eliminated, thus five poly pitches (PP) is reduced from the total width of the macro 12. The area G is illustrated by the dashed rectangle and is aligned with the power tap region 25a along the Y direction. Similarly, the power tap region 25b and a corresponding aligned portion of the memory edge region 30 and the memory filler region 35 may also be eliminated, thus five poly pitches (PP) is reduced from the total width of the macro 12. Thus, the footprint area of the macro 12 of the memory device 10L is reduced from that of the memory device 101 by about 2% to about 30%. In such embodiments, power supply to the memory cells of the memory cell region 15 may be provided by the FTV rail 190′, which extends through the memory edge region 30 and is similar but shorter than the FTV rail 190 along the X-direction. Similar as described above for FIGS. 24-25, the voltage drop may be reduced by greater than about 80 mV.

Although not depicted, it is understood that the memory devices 10A, 10B, . . . , and 10F described above may similarly eliminate the power tap regions 25 and corresponding aligned portions (e.g., in the area G) of the memory edge region 30 and the memory filler region 35, thus the footprint area of the macro 12 of the memory device 10 may be reduced.

It is understood that the above description for the portion of the memory device 10 in the area A may be applied similarly to a portion of the memory device 10 in an area A′. The area A and the area A′ are symmetric with respect to a mirror axis H-H as in FIG. 1, which is a central line of the macro 12. Thus, the portion in the area A′ includes a portion of the memory edge region 30b. The portion in the area A and the portion in the area A′ of a memory device 10 may have various combinations of the embodiments described above. In some embodiments, the memory edge region 30a and 30b may include a same or different through conductive features described above and may be connected to power lines having a same or different voltage potential. In an example, a memory device 10 may have the portion in the area A similar as described for FIGS. 5-8, and the portion in the area A′ similar as described for FIGS. 14-16. In another example, the portions of the memory device 10 in the areas A and A′ are both similar as described for FIGS. 5-8. In yet another example, the portion of the memory device 10 in the area A is similar to the embodiments described above, such as similar as described for FIGS. 5-8, and the portion of the memory device 10 in the area A′ excludes a through conductive feature as described above.

Based on the above discussions, it can be seen that the present disclosure offers advantages. It is understood, however, that other embodiments may offer additional advantages, and not all advantages are necessarily disclosed herein, and that no particular advantage is required for all embodiments. For example, the present disclosure provides a memory device that has additional and/or improved through conductive features for power supply, which reduces the total resistance of the power supply features, thus reduces voltage drop and/or power consumption. In addition, by eliminating certain region(s), the area of a memory macro having a certain number of memory cells may be reduced by about 2% to about 30%. By having the additional and/or improved through conductive features for power supply, the memory devices disclosed herein may include an increased number of memory cells without impacting performance of the memory cells.

In one exemplary aspect, the present disclosure is directed to a semiconductor device. The semiconductor device includes a device layer, a frontside interconnect structure disposed over the device layer and including a frontside power line, and a backside interconnect structure disposed below the device layer and including a backside power line. The device layer includes a memory cell region including a plurality of memory cells, a logic region disposed adjacent to a first edge of the memory cell region, and an edge region disposed along a second edge of the memory cell region. The second edge is perpendicular to the first edge. The edge region includes a through conductive feature electrically connected to the frontside power line and the backside power line. The through conductive feature includes a backside via electrically connected to the backside power line, an epitaxial feature disposed on the backside via, a source/drain contact disposed on the epitaxial feature, and a top via disposed on the source/drain contact and electrically connected to the frontside power line.

In some embodiments, the frontside power line and the backside power line are positive power supply lines. In some embodiments, the frontside power line and the backside power line are ground lines. In some embodiments, the epitaxial feature is a first epitaxial feature and the backside via is a first backside via, the plurality of memory cells include a second epitaxial feature electrically connected to the backside power line by a second backside via and backside metal lines, and the source/drain contact extends to be over and in direct contact with the second epitaxial feature. In some embodiments, the edge region is a first edge region, the through conductive feature is a first through conductive feature, the frontside power line is a first frontside power line, and the backside power line is a first backside power line, the device layer further includes a second edge region disposed along a third edge of the memory cell region, the third edge being opposite to the second edge, the frontside interconnect structure further includes a second frontside power line, the backside interconnect structure further includes a second backside power line, and the second edge region includes a second through conductive feature electrically connected to the second frontside power line and the second backside power line. In some embodiments, the first frontside power line and the first backside power line are positive power supply lines, and the second frontside power line and the second backside power line are ground lines. In some embodiments, the first frontside power line, the first backside power line, the second frontside power line, and the second backside power line are electrically connected to a same voltage potential. In some embodiments, the epitaxial feature is a first epitaxial feature of an active region, the active region further includes a second epitaxial feature, and the backside via is in direct contact with a bottom surface of the second epitaxial feature. In some embodiments, the through conductive feature is a first through conductive feature, the device layer further includes a power tap region disposed between the first edge of the logic region and the memory cell region, and the power tap region includes a second through conductive feature electrically connected to the frontside power line and the backside power line.

In another exemplary aspect, the present disclosure is directed to a semiconductor device. The semiconductor device includes a device layer, a frontside interconnect structure disposed over the device layer and including a first frontside power line and a second frontside power line, and a backside interconnect structure disposed below the device layer and including a first backside power line and a second backside power line. The device layer includes a memory cell region including a plurality of functional memory cells, a power tap region disposed adjacent to and along a first edge of the memory cell region, a logic region disposed adjacent to the power tap region, and an edge region free of functional memory cells and disposed along a second edge of the memory cell region. The power tap region is disposed between the logic region and the memory cell region. The second edge is perpendicular to the first edge. The edge region includes a first through conductive feature electrically connected to the first frontside power line and the first backside power line. The power tap region includes a second through conductive feature electrically connected to the second frontside power line and the second backside power line.

In some embodiments, the first through conductive feature includes a backside via electrically connected to the first backside power line, an epitaxial feature disposed on the backside via, a source/drain contact disposed on the epitaxial feature, and a top via disposed on the source/drain contact and electrically connected to the first frontside power line. In some embodiments, the edge region further includes a third through conductive feature electrically connected to the first frontside power line and the first backside power line, the first through conductive feature and the third through conductive feature are arranged along a direction parallel to the second edge of the memory cell region. In some embodiments, the first through conductive feature includes a backside contact electrically connected to the first backside power line, and a frontside contact disposed over the backside contact and electrically connected to the first frontside power line. In some embodiments, the first frontside power line, the first backside power line, the second frontside power line, and the second backside power line are positive power supply lines. In some embodiments, the first frontside power line, the first backside power line, the second frontside power line, and the second backside power line are ground lines. In some embodiments, the plurality of functional memory cells include an active region having an epitaxial feature, the plurality of functional memory cells includes a conductive contact connecting the first through conductive feature and the epitaxial feature, and a lengthwise direction of the conductive contact is perpendicular to a lengthwise direction of the active region.

In yet another exemplary aspect, the present disclosure is directed to a semiconductor device. The semiconductor device includes a device layer, a frontside power line disposed over the device layer, and a backside power line disposed below the device layer. The device layer includes a memory cell region including a plurality of memory cells. The plurality of memory cells include a first active region extending lengthwise along a first direction. The device layer further includes a logic region disposed adjacent to the memory cell region and extending lengthwise along a second direction perpendicular to the first direction, and an edge region disposed adjacent to the memory cell region and extending lengthwise along the first direction. The edge region includes a second active region extending lengthwise along the first direction. The edge region includes a through conductive feature electrically connected to the frontside power line and the backside power line, and the second active region is disposed between the through conductive feature and the first active region.

In some embodiments, the through conductive feature extends lengthwise along the first direction. In some embodiments, the edge region includes a third active region extending lengthwise along the first direction, and the through conductive feature extends through the third active region. In some embodiments, the first active region, the second active region, and the third active region are disposed over a same p-type well.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device layer comprising:
a memory cell region comprising a plurality of memory cells,
a logic region disposed adjacent to a first edge of the memory cell region, and
an edge region disposed along a second edge of the memory cell region, wherein the second edge is perpendicular to the first edge;
a frontside interconnect structure disposed over the device layer and comprising a frontside power line; and
a backside interconnect structure disposed below the device layer and comprising a backside power line,
wherein the edge region comprises a through conductive feature electrically connected to the frontside power line and the backside power line, and
wherein the through conductive feature comprises a backside via electrically connected to the backside power line, an epitaxial feature disposed on the backside via, a source/drain contact disposed on the epitaxial feature, and a top via disposed on the source/drain contact and electrically connected to the frontside power line.

2. The semiconductor device of claim 1, wherein the frontside power line and the backside power line are positive power supply lines.

3. The semiconductor device of claim 1, wherein the frontside power line and the backside power line are ground lines.

4. The semiconductor device of claim 3, wherein the epitaxial feature is a first epitaxial feature and the backside via is a first backside via,
wherein the plurality of memory cells comprise a second epitaxial feature electrically connected to the backside power line by a second backside via and backside metal lines,
wherein the source/drain contact extends to be over and in direct contact with the second epitaxial feature.

5. The semiconductor device of claim 1, wherein the edge region is a first edge region, the through conductive feature is a first through conductive feature, the frontside power line is a first frontside power line, and the backside power line is a first backside power line,
wherein the device layer further comprises a second edge region disposed along a third edge of the memory cell region, the third edge being opposite to the second edge,
wherein the frontside interconnect structure further comprises a second frontside power line,
wherein the backside interconnect structure further comprises a second backside power line, and
wherein the second edge region comprises a second through conductive feature electrically connected to the second frontside power line and the second backside power line.

6. The semiconductor device of claim 5, wherein the first frontside power line and the first backside power line are positive power supply lines, and
wherein the second frontside power line and the second backside power line are ground lines.

7. The semiconductor device of claim 5, wherein the first frontside power line, the first backside power line, the second frontside power line, and the second backside power line are electrically connected to a same voltage potential.

8. The semiconductor device of claim 1, wherein the epitaxial feature is a first epitaxial feature of an active region,
wherein the active region further comprises a second epitaxial feature, and
wherein the backside via is in direct contact with a bottom surface of the second epitaxial feature.

9. The semiconductor device of claim 1, wherein the through conductive feature is a first through conductive feature,
wherein the device layer further comprises a power tap region disposed between the first edge of the logic region and the memory cell region, and
wherein the power tap region comprises a second through conductive feature electrically connected to the frontside power line and the backside power line.

10. A semiconductor device, comprising:
a device layer comprising:
a memory cell region comprising a plurality of functional memory cells,
a power tap region disposed adjacent to and along a first edge of the memory cell region,
a logic region disposed adjacent to the power tap region, wherein the power tap region is disposed between the logic region and the memory cell region, and
an edge region free of functional memory cells and disposed along a second edge of the memory cell region, wherein the second edge is perpendicular to the first edge;
a frontside interconnect structure disposed over the device layer and comprising a first frontside power line and a second frontside power line; and
a backside interconnect structure disposed below the device layer and comprising a first backside power line and a second backside power line,
wherein the edge region comprises a first through conductive feature electrically connected to the first frontside power line and the first backside power line, and
wherein the power tap region comprises a second through conductive feature electrically connected to the second frontside power line and the second backside power line.

11. The semiconductor device of claim 10, wherein the first through conductive feature comprises a backside via electrically connected to the first backside power line, an epitaxial feature disposed on the backside via, a source/drain contact disposed on the epitaxial feature, and a top via disposed on the source/drain contact and electrically connected to the first frontside power line.

12. The semiconductor device of claim 11, wherein the edge region further comprises a third through conductive feature electrically connected to the first frontside power line and the first backside power line,
wherein the first through conductive feature and the third through conductive feature are arranged along a direction parallel to the second edge of the memory cell region.

13. The semiconductor device of claim 10, wherein the first through conductive feature comprises:
a backside contact electrically connected to the first backside power line, and
a frontside contact disposed over the backside contact and electrically connected to the first frontside power line.

14. The semiconductor device of claim 10, wherein the first frontside power line, the first backside power line, the second frontside power line, and the second backside power line are positive power supply lines.

15. The semiconductor device of claim 10, wherein the first frontside power line, the first backside power line, the second frontside power line, and the second backside power line are ground lines.

16. The semiconductor device of claim 15, wherein the plurality of functional memory cells comprise an active region having an epitaxial feature,
wherein the plurality of functional memory cells comprises a conductive contact connecting the first through conductive feature and the epitaxial feature, and wherein a lengthwise direction of the conductive contact is perpendicular to a lengthwise direction of the active region.

17. A semiconductor device, comprising:
a device layer comprising:
a memory cell region comprising a plurality of memory cells, wherein the plurality of memory cells comprise a first active region extending lengthwise along a first direction,
a logic region disposed adjacent to the memory cell region and extending lengthwise along a second direction perpendicular to the first direction, and
an edge region disposed adjacent to the memory cell region and extending lengthwise along the first direction, wherein the edge region comprises a second active region extending lengthwise along the first direction;
a frontside power line disposed over the device layer; and
a backside power line disposed below the device layer,
wherein the edge region comprises a through conductive feature electrically connected to the frontside power line and the backside power line, and
wherein the second active region is disposed between the through conductive feature and the first active region.

18. The semiconductor device of claim 17, wherein the through conductive feature extends lengthwise along the first direction.

19. The semiconductor device of claim 17, the edge region comprises a third active region extending lengthwise along the first direction, and
wherein the through conductive feature extends through the third active region.

20. The semiconductor device of claim 19, wherein the first active region, the second active region, and the third active region are disposed over a same p-type well.
